(19) United States
(12) Patent Application Publication
(10) Pub. No.: US 2026/0190757 A1
(43) Pub. Date: Jul. 2, 2026

(54) DISPLAY DEVICE

(71) Applicant: LG Display Co., Ltd., Seoul (KR)

(72) Inventors: SeokHyun Kim, Seoul (KR); KwanSoo Kim, Seoul (KR)

(73) Assignee: LG Display Co., Ltd., Seoul (KR)

(21) Appl. No.: 19/399,407

(22) Filed: Nov. 24, 2025

(30) Foreign Application Priority Data
Dec. 26, 2024 (KR) 10-2024-0196872

(51) Int. Cl. H10K 59/80; H10K 59/124

(52) U.S. Cl. CPC H10K 59/80517; H10K 59/124

(57) ABSTRACT

A display device includes a substrate, an optical area which includes a first emission area and a transmissive area, and a normal area which includes a second emission area and encloses the optical area. The display device further includes a planarization layer which is disposed on the substrate and is disposed in the optical area and the normal area. The display device further includes a first light emitting diode which is disposed on the planarization layer in the second emission area and includes a first-first electrode, a first organic layer disposed on the first-first electrode, and a second-first electrode disposed on the first organic layer. The display device further includes a first deposition stop layer disposed on the second-first electrode in the second emission area and at least one second deposition stop layer disposed on the planarization layer in a part of the transmissive area.

### CROSS-REFERENCE TO RELATED APPLICATIONS

This application claims the benefit of and priority to Korean Patent Application No. 10-2024-0196872 filed on December 26, 2024, in the Korean Intellectual Property Office, the entire contents of which are incorporated herein by reference for all purposes.

### BACKGROUND

### 1. Technical Field

The present disclosure relates to a display device, and particularly to, for example, without limitation, a display device in which a transmittance of an area in which an optical electronic device is disposed is improved.

### 2. Description of Related Art

A field of a display device which visually expresses electrical information signals has been rapidly developed and studies are continued to improve performances of various display devices, such as a thin-thickness, a light weight, and low power consumption.

A representative display device may include a liquid crystal display device (LCD), a field emission display device (FED), an electro-wetting display device (EWD), and an organic light emitting display device (OLED).

An electroluminescent display device which is represented by an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), it is expected to be utilized in various fields.

Recently, a multi-media function of a mobile terminal is being improved. For example, a display device in which an optical electronic device such as a camera or a sensor is embedded on a front surface as a default has been developed. However, the camera or the sensor disposed on the front surface of the display device restricts a screen design. In order to reduce a space occupied by the camera or the sensor on the front surface of the display device, a design including a notch or a punch hole may be applied. However, the screen size is still restricted so that it is difficult to implement a full-screen display.

In order to implement the full-screen display, a method for providing an area in which low-resolution pixels are disposed in the screen of the display device and placing the camera and/or various sensors in an area in which the low-resolution pixels are disposed is being proposed.

The description of related art should not be considered prior art merely because it is mentioned in or associated with this section. The description of related art includes information that describes one or more aspects of the subject technology, and the description in this section does not limit the scope of the invention.

### SUMMARY

An aspect of the present disclosure provides a display device in which a transmittance is improved and a luminance is increased in a transmissive area in which an optical electronic device, such as a camera or a sensor, is disposed.

An aspect of the present disclosure provides a display device with an improved ultraviolet (UV) reliability of a transmissive area in which an optical electronic device, such as a camera or a sensor, is disposed.

Aspects of the present disclosure are not limited to the above-mentioned aspects, and other aspects, which are not mentioned above, can be clearly understood by those skilled in the art from the following descriptions.

According to an example embodiment of the present disclosure, there is provided a display device. The display device includes a substrate, an optical area which includes a first emission area and a transmissive area, and a normal area which includes a second emission area and encloses the optical area. The display device further includes a planarization layer which is disposed on the substrate and is disposed in the optical area and the normal area. The display device further includes a first light emitting diode which is disposed on the planarization layer in the second emission area and includes a first-first electrode, a first organic layer disposed on the first-first electrode, and a second-first electrode disposed on the first organic layer. The display device further includes a first deposition stop layer disposed on the second-first electrode on the second emission area and at least one second deposition stop layer disposed on the planarization layer in a part of the transmissive area.

Other detailed matters of the example embodiments are included in the detailed description and the drawings.

According to an example embodiment of the present disclosure, a deposition stop layer is disposed in an optical area to improve a transmittance of an optical area.

According to an example embodiment of the present disclosure, a light emitting diode disposed in the optical area has a micro cavity structure to improve a luminance of an optical area, thereby driving the display device at a low power to reduce power consumption.

According to the example embodiment of the present disclosure, a second electrode of a light emitting diode is formed with a multi-layered structure in a part of the optical area, thereby improving a UV reliability of the optical area.

According to the example embodiment of the present disclosure, a deposition stop layer is disposed in a normal area to suppress a thickness of a second electrode of a light emitting diode from increasing, thereby suppressing degradation of a luminance of a normal area.

The effects of the present disclosure are not limited to the aforementioned effects, and other effects, which are not mentioned above, will be apparently understood to a person having ordinary skill in the art from the following description.

The aspects of the present disclosure, the means for achieving the aspects, and the effects of the present disclosure described above do not specify essential features of the claims, and, thus, the scope of the claims is not limited to the disclosure of the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIGS. 1A to 1D are schematic plan views of a display device according to an example embodiment of the present disclosure;

FIG. 2 is a system diagram of a display device according to an example embodiment of the present disclosure;

FIG. 3 is an equivalent circuit diagram of a sub pixel in a display panel according to an example embodiment of the present disclosure;

FIG. 4 is a view illustrating an example that a sub pixel of a display area according to an example embodiment of the present disclosure is disposed;

FIG. 5A is a view illustrating an example that a signal line is disposed in each of a first optical area and a normal area according to an example embodiment of the present disclosure;

FIG. 5B is a view illustrating an example that a signal line is disposed in each of a second optical area and a normal area according to an example embodiment of the present disclosure;

FIG. 6 is a plan view schematically illustrating a normal area of a display device according to an example embodiment of the present disclosure.

FIG. 7 is a cross-sectional view taken along A-B of FIG. 6;

FIG. 8 is an enlarged view of an area X of FIG. 7;

FIG. 9 is a plan view schematically illustrating a first optical area of a display device according to an example embodiment of the present disclosure;

FIG. 10 is a cross-sectional view taken along the line C-D of FIG. 9;

FIG. 11 is an enlarged view of an area Y of FIG. 10;

FIG. 12 is an enlarged view of an area Z of FIG. 10;

FIG. 13 is a plan view schematically illustrating a mask used for forming a second deposition stop layer;

FIG. 14 is a plan view schematically illustrating a mask used for forming a third deposition stop layer;

FIG. 15 is a table for comparing an efficiency of a light emitting diode of a display device according to Comparative Example 1 and an efficiency of a light emitting diode of a display device according to Example 1;

FIG. 16 is a graph for comparing a transmittance of a second electrode of a light emitting diode disposed in a normal area and a transmittance of a second electrode of a light emitting diode disposed in a first optical area of a display device according to an example embodiment of the present disclosure;

FIG. 17 is a table for comparing a panel transmittance of a normal area and a panel transmittance of a first optical area of a display device according to an example embodiment of the present disclosure;

FIG. 18 is a plan view schematically illustrating a first optical area of a display device according to another example embodiment of the present disclosure; and

FIG. 19 is a plan view schematically illustrating a first optical area of a display device according to still another example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described herein in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. In one or more examples, unless the context clearly indicates otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms such as a first direction, a second direction, a row direction, a column direction, a front direction, a rear direction, a horizontal direction, a vertical direction, or the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements. Moreover, “at least some,” “some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise. In one or more aspects, unless stated otherwise, the term “nth” may refer to “nnd” (e.g., 2nd where n is 2), or “nrd” (e.g., 3rd where n is 3), and n may be a natural number or a whole number.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

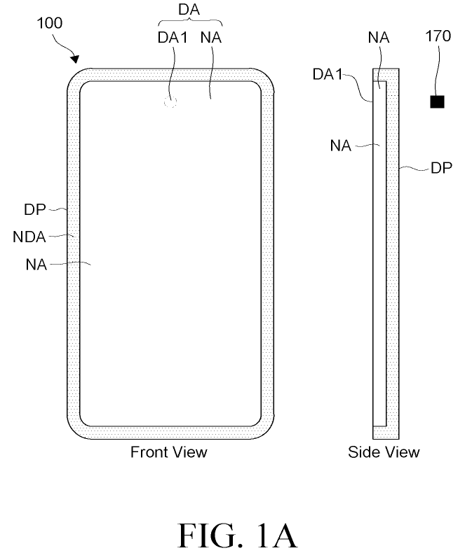

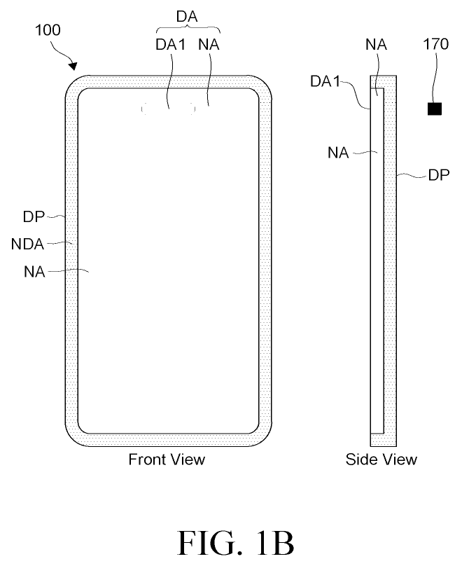

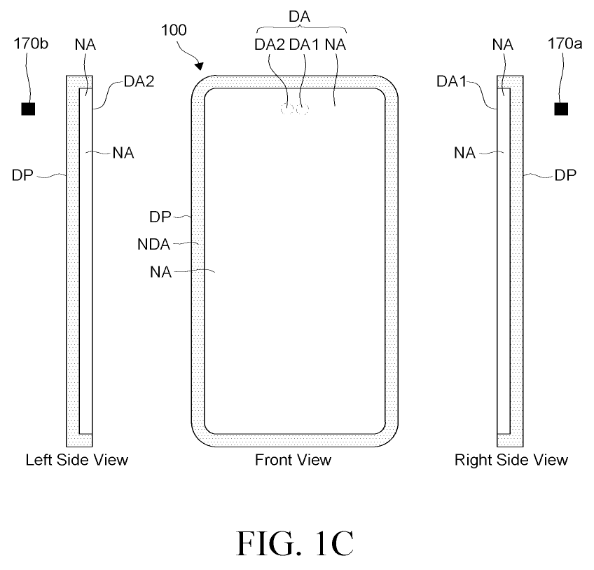

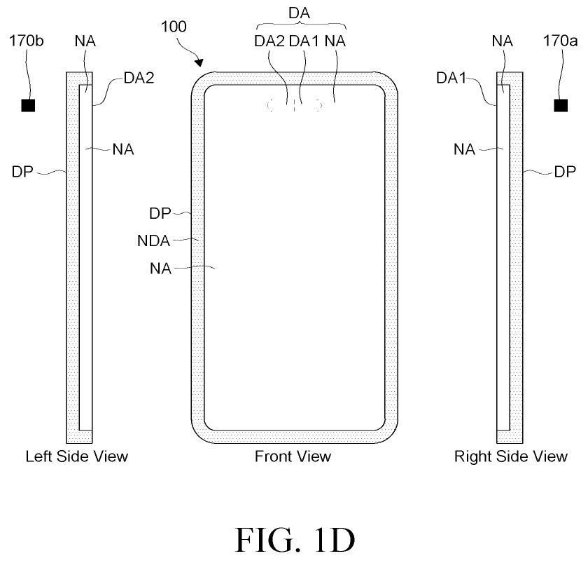

FIGS. 1A to 1D are schematic plan views of a display device according to an example embodiment of the present disclosure.

Referring to FIGS. 1A to 1D, a display device 100 according to an example embodiment of the present disclosure may include a display panel DP which displays images and one or more optical electronic devices 170, 170a, and 170b. The optical electronic devices 170, 170a, and 170b may include a light receiving device which receives light, such as a camera or a sensor.

The display panel DP is a panel for displaying images to a user.

The display panel DP may include a display element which displays images, a driving element which drives the display element, and wiring lines which transmit various signals to the display element and the driving element. The display element may be defined in different ways depending on a type of the display panel DP. For example, when the display panel DP is an organic light emitting display panel, the display element may be an organic light emitting diode which includes a first electrode (anode or cathode), an organic layer, and a second electrode (cathode or anode).

For example, when the display panel DP is a liquid crystal display panel, the display element may be a liquid crystal display element. Further, the display device 100 according to the example embodiment of the present disclosure may be a flexible display device.

Hereinafter, even though the display panel DP is assumed as an organic light emitting display panel, the display panel DP is not limited to the organic light emitting display panel.

In the meantime, the display panel DP may be configured to include a substrate, a plurality of insulating films, a transistor layer, and a light emitting diode layer on the substrate.

The display panel DP may include a plurality of sub pixels for displaying images and various signal lines for driving the plurality of sub pixels.

The display panel DP may include a display area DA in which images are displayed and a non-display area NDA in which no image is displayed.

In the display area DA, a plurality of sub pixels which configures the plurality of pixels and a circuit for driving the plurality of sub pixels may be disposed. The plurality of sub pixels is minimum units which configure the display area DA and a display element may be disposed in each of the plurality of sub pixels. The plurality of sub pixels may configure a pixel.

For example, an organic light emitting diode which may include a first electrode, an organic layer, and a second electrode may be disposed in each of the plurality of sub pixels, but it is not limited thereto.

Further, a circuit for driving the plurality of sub pixels may include a driving element and a wiring line. For example, the circuit may be configured by a thin film transistor, a storage capacitor, a gate line, and a data line, but is not limited thereto.

The non-display area NDA is bent so as not to be seen from a front surface or blocked by a case (not illustrated) and is also referred to as a bezel area.

In the non-display area NDA, various wiring lines and circuits for driving the organic light emitting diode of the display area DA may be disposed.

For example, in the non-display area NDA, a link line which transmits signals to the plurality of sub pixels and circuits of the display area DA, a gate-in-panel (GIP) line, or a driving IC, such as a gate driver IC or a data driver IC, may be disposed, but it is not limited thereto.

Even though in FIGS. 1A to 1D, it is illustrated that the non-display area NDA encloses a quadrangular display area DA, shapes and placements of the display area DA and the non-display area NDA are not limited to the example illustrated in FIGS. 1A to 1D. The display area DA and the non-display area NDA may have shapes suitable for a design of an electronic device including the display device 100. For example, an example shape of the display area DA may be a pentagon, a hexagon, a circle, or an oval.

The display device 100 may further include an additional element associated with a function other than a function of driving a pixel. For example, the display device 100 may further include additional elements which provide a touch sensing function, a user authentication function (for example, fingerprint recognition), a multilevel pressure sensing function, or a tactile feedback function. The above-mentioned additional elements may be located in the non-display area NDA and/or an external circuit which is connected to a connecting interface.

Referring to FIGS. 1A to 1D, in the display device 100 according to the example embodiments of the present disclosure, one or more optical electronic devices 170, 170a, and 170b may be electronic components located below the display panel DP (opposite to a viewing surface).

Light enters the front surface (viewing surface) of the display panel DP and passes through the display panel DP to be transmitted to one or more optical electronic devices 170, 170a, and 170b located below (an opposite side of a viewing surface of) the display panel DP.

One or more optical electronic devices 170, 170a, and 170b may be devices which receive light which passes through the display panel DP to perform a predetermined function according to received light.

For example, the optical electronic devices 170, 170a, and 170b may include one or more of an image capturing device, such as a camera (image sensor) and a sensing sensor such as an illumination sensor and a proximity sensor.

Referring to FIGS. 1A to 1D, in the display device 100 according to the example embodiments of the present disclosure, the display area DA may include a normal area NA and one or more optical areas DA1 and DA2.

One or more optical areas DA1 and DA2 may be areas overlapping one or more optical electronic devices 170, 170a, and 170b.

According to an example of FIG. 1A, the display area DA may include a normal area NA and a first optical area DA1. Here, at least a part of the first optical area DA1 may overlap a first optical electronic device 170.

Even though in FIG. 1A, a circular structure of the first optical area DA1 is illustrated, a shape of the first optical area DA1 according to the example embodiment of the present disclosure is not limited thereto. For example, as illustrated in FIG. 1B, the first optical area DA1 may have an octagonal shape, and also may be formed of various polygonal shapes.

According to an example of FIG. 1C, the display area DA may include a normal area NA, a first optical area DA1, and a second optical area DA2. In an example of FIG. 1C, the normal area NA may be disposed between the first optical area DA1 and the second optical area DA2. Here, at least a part of the first optical area DA1 may overlap the first optical electronic device 170a and at least a part of the second optical area DA2 may overlap the second optical electronic device 170b.

According to an example of FIG. 1D, the display area DA may include a normal area NA, a first optical area DA1, and a second optical area DA2. In an example of FIG. 1D, the normal area NA is not disposed between the first optical area DA1 and the second optical area DA2. That is, the first optical area DA1 and the second optical area DA2 may be in contact with each other. Here, at least a part of the first optical area DA1 may overlap the first optical electronic device 170a and at least a part of the second optical area DA2 may overlap the second optical electronic device 170b.

In one or more optical areas DA1 and DA2, both an image display structure and a light transmission structure need to be formed.

That is, one or more optical areas DA1 and DA2 are a partial area of the display area DA so that in one or more optical areas DA1 and DA2, a sub pixel for displaying an image needs to be disposed. In one or more optical areas DA1 and DA2, a light transmission structure which transmits light to one or more optical electronic devices 170, 170a, and 170b needs to be formed.

One or more optical electronic devices 170, 170a, and 170b are devices which need to receive light, but are located behind the display panel DP (below, in an opposite side of a viewing surface) to receive light which passes through the display panel DP.

One or more optical electronic devices 170, 170a, and 170b are not exposed to the front surface (the viewing surface) of the display panel DP. Accordingly, when a user sees the front surface of the display device 100, the optical electronic devices 170, 170a, and 170b are not seen to the user.

For example, the first optical electronic devices 170 and 170a may be cameras and the second optical electronic device 170b may be a sensing sensor such as a proximity sensor or an illumination sensor. For example, the sensing sensor may be an infrared sensor which senses an infrared ray.

In contrast, the first optical electronic devices 170 and 170a may be sensing sensors and the second optical electronic device 170b may be a camera.

Hereinafter, for the convenience of description, an example that the first optical electronic devices 170 and 170a are cameras and the second optical electronic device 170b is a sensing sensor will be described. Here, the camera may be a camera lens or an image sensor.

If the first optical electronic devices 170 and 170a are cameras, the camera may be a front side camera which is located behind (below) the display panel DP, but captures a front direction of the display panel DP. Accordingly, the user may take a picture through a camera which is not seen from the viewing surface while watching the viewing surface of the display panel DP.

The normal area NA and one or more optical areas DA1 and DA2 included in the display area DA are areas in which images may be displayed. The normal area NA is an area in which there is no need to form a light transmission structure and one or more optical areas DA1 and DA2 are areas in which the light transmission structure needs to be formed.

Accordingly, one or more optical areas DA1 and DA2 need to have a predetermined level or higher of transmittance and the normal area NA does not have light transmissivity or has a transmittance lower than a predetermined level.

For example, one or more optical areas DA1 and DA2 and the normal area NA may have different resolutions, sub pixel placement structures, numbers of sub pixels per unit area, electrode structures, line structures, electrode placement structures, or line placement structures.

For example, the number of sub pixels per unit area in one or more optical areas DA1 and DA2 may be smaller than the number of sub pixels per unit area in the normal area NA. That is, the resolution of one or more optical areas DA1 and DA2 may be lower than a resolution of a normal area NA. At this time, the number of sub pixels per unit area is a unit of measuring a resolution and may also be referred to a pixels per inch (PPI) indicating the number of pixels in one inch.

For example, the number of sub pixels per unit area in the first optical area DA1 may be smaller than the number of sub pixels per unit area in the normal area NA. Further, the number of sub pixels per unit area in the second optical area DA2 may be equal to or larger than the number of sub pixels per unit area in the first optical area DA1.

The first optical area DA1 may have various shapes such as a circle, an oval, a rectangle, a hexagon, or an octagon. The second optical area DA2 may have various shapes such as a circle, an oval, a rectangle, a hexagon, or an octagon. The first optical area DA1 and the second optical area DA2 may have the same shape or different shapes.

Referring to FIG. 1D, when the first optical area DA1 and the second optical area DA2 are in contact with each other, the entire optical area including the first optical area DA1 and the second optical area DA2 may have various shapes, such as a circle, an oval, a rectangle, a hexagon, or an octagon.

Hereinafter, for the convenience of description, an example that the first optical area DA1 and the second optical area DA2 are circles will be described.

In the display device 100 according to the example embodiment of the present disclosure, when the first optical electronic device 170 and 170b which are hidden below the display panel DP without being exposed to the outside is a camera, the display device 100 according to the example embodiment of the present disclosure may be said as a display to which a under display camera (UDC) technique is applied.

By doing this, in the display device 100 according to the example embodiment of the present disclosure, there is no need to form a notch or a camera hole for exposing the camera in the display panel DP, so that the area of the display area DA is not reduced.

Accordingly, there is no need to form a notch or a camera hole for exposing the camera in the display panel DP so that a size of the bezel area is reduced and design constraints are not provided to increase a degree of freedom of design.

In the display device 100 according to the example embodiment of the present disclosure, even though one or more optical electronic devices 170, 170a, and 170b are hidden behind the display panel DP, one or more optical electronic devices 170, 170a, and 170b need to normally receive the light to normally perform a determined function.

Further, in the display device 100 according to the example embodiment of the present disclosure, even though one or more optical electronic devices 170, 170a, and 170b are hidden behind the display panel DP and overlap the display area DA, in one or more optical areas DA1 and DA2 overlapping one or more optical electronic devices 170, 170a, and 170b in the display area DA, the image needs to be normally displayed.

Accordingly, the display device 100 according to the example embodiment of the present disclosure may have a structure which improves a transmittance of the first optical area DA1 and the second optical area DA2 overlapping the optical electronic devices 170, 170a, and 170b.

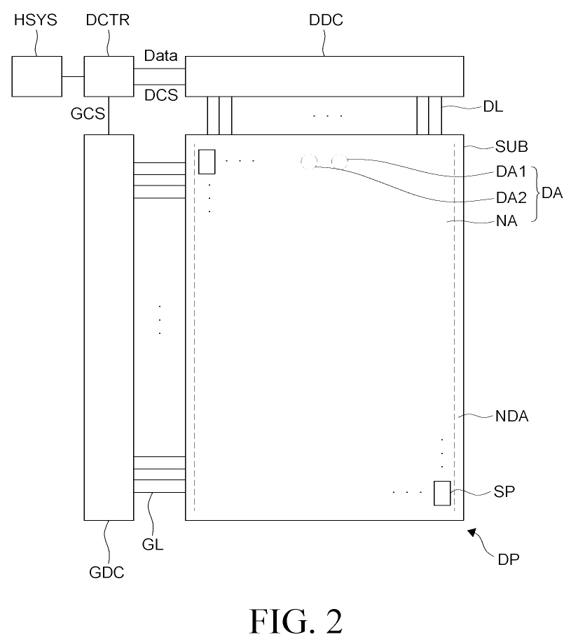

FIG. 2 is a system diagram of a display device according to an example embodiment of the present disclosure.

Referring to FIG. 2, the display device 100 may include a display panel DP and a display driving circuit, as components for displaying images. The display driving circuit is a circuit for driving the display panel DP and may include a data driving circuit DDC, a gate driving circuit GDC, a display controller DCTR, and the like.

The display panel DP may include a display area DA in which images are displayed and a non-display area NDA in which no image is displayed.

The non-display area NDA may be an outer peripheral area of the display area DA and be also referred to as a bezel area. All or a part of the non-display area NDA may be an area which is visible from a front surface of the display device 100 or is bent so as not to be seen from the front surface of the display device 100.

The display panel DP may include a substrate SUB and a plurality of sub pixels SP disposed on the substrate SUB. Further, the display panel DP may further include various types of signal lines to drive the plurality of sub pixels SP.

Structures of the plurality of sub pixels SP may vary depending on a type of the display device 100. For example, when the display device 100 is a self-emitting display device in which the sub pixel SP emits by itself, each sub pixel SP may include a self-emitting device, one or more transistors, and one or more capacitors.

Various types of signal lines may include a plurality of data lines DL which transmits data signals (also referred to as data voltages or image signals) and a plurality of gate lines GL which transmits gate signals (also referred to as scan signals).

The plurality of data lines DL and the plurality of gate lines GL may intersect each other. Each of the plurality of data lines DL may be disposed to extend in a first direction. Each of the plurality of gate lines GL may be disposed to extend in a second direction. Here, the first direction may be a column direction and the second direction may be a row direction. Alternatively, the first direction is a row direction and the second direction may be a column direction.

The data driving circuit DDC is a circuit for driving a plurality of data lines DL and may output data signals to the plurality of data lines DL. The gate driving circuit GDC is a circuit for driving a plurality of gate lines GL and may output gate signals to the plurality of gate lines GL.

The display controller DCTR is a device for controlling a data driving circuit DDC and a gate driving circuit GDC and may control a driving timing for the plurality of data lines DL and a driving timing for the plurality of gate lines GL.

The display controller DCTR supplies a data driving control signal DCS for controlling the data driving circuit DDC to the data driving circuit DDC and may supply a gate driving control signal GCS for controlling the gate driving circuit GDC to the gate driving circuit GDC.

The display controller DCTR receives input image data from a host system HSYS to supply image data Data to the data driving circuit DDC based on the input image data.

The display device 100 according to the example embodiments of the present disclosure may include a touch sensor and a touch sensing circuit to further provide not only an image displaying function but also a touch sensing function. The touch sensing circuit senses the touch sensor to detect whether a touch occurs by a touch object, such as a finger or a pen or detect a touch position.

The touch sensing circuit may further include a touch driving circuit which drives and senses the touch sensor to generate and output touch sensing data and a touch controller which senses the touch generation or detects the touch position using the touch sensing data.

The touch sensor may include a plurality of touch electrodes. The touch sensor may further include a plurality of touch lines which electrically connects the plurality of touch electrodes and the touch driving circuit.

The touch sensor may be provided at the outside of the display panel DP as a touch panel or provided in the display panel DP.

When the touch sensor is provided at the outside of the display panel DP as a touch panel type, the touch sensor is referred to as an external type. When the touch sensor is an external type, the touch panel and the display panel DP are separately manufactured to be combined during an assembling process. The external type touch panel may include a substrate for a touch panel and a plurality of touch electrodes on the substrate for a touch panel.

When the touch sensor is provided in the display panel DP, a touch sensor may be formed on the substrate SUB together with signal lines and electrodes related to the display driving, during the process of manufacturing the display panel DP.

The touch driving circuit and the touch controller included in the touch sensing circuit may be implemented as separate devices or implemented as one device. Further, the touch driving circuit and the data driving circuit DDC may be implemented as separate devices or implemented as one device.

Further, the display device 100 may further include a power supply circuit which supplies various powers to the display driving circuit and/or the touch sensing circuit.

The display device 100 according to the example embodiments of the present disclosure may be mobile terminals such as smart phones or tablets or may be monitors or television TV with various sizes, but is not limited thereto and may be a display device of various types or various sizes which express information or images.

As described above, in the display panel DP, the display area DA may include a normal area NA and one or more optical areas DA1 and DA2.

The normal area NA and one or more optical area DA1 and DA2 are areas which are capable of displaying images. However, the normal area NA is an area in which there is no need to form a light transmission structure and one or more optical areas DA1 and DA2 are areas in which the light transmission structure needs to be formed.

As described above, in the display panel DP, the display area DA may include a normal area NA and one or more optical areas DA1 and DA2.

Hereinafter, for the convenience of description, it is assumed that the display area DA includes both the first optical area DA1 and the second optical area DA2 (see FIGS. 1C and 1D).

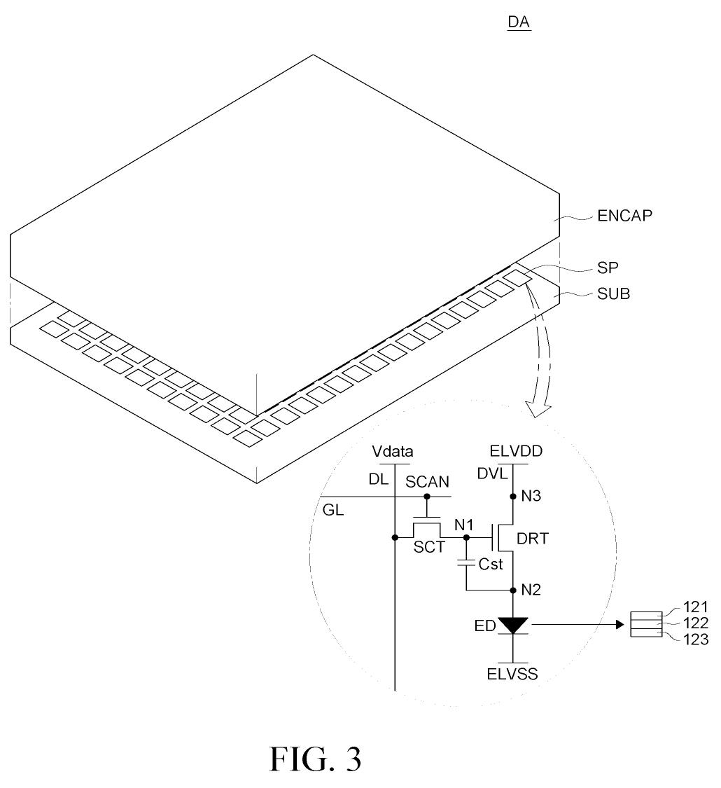

FIG. 3 is an equivalent circuit diagram of a sub pixel in a display panel according to an example embodiment of the present disclosure.

Each of the sub pixels SP disposed in the normal area NA, the first optical area DA1, and the second optical area DA2 included in the display area DA of the display panel DP may include a light emitting diode ED, a driving transistor DTR, a scan transistor SCT, and a storage capacitor Cst. The driving transistor DTR drives the light emitting diode ED and the scan transistor SCT transmits a data voltage VDATA to a first node N1 of the driving transistor DRT, the storage capacitor Cst maintains a constant voltage for one frame.

The driving transistor DRT may include a first node N1 to which the data voltage is applied, a second node N2 which is electrically connected to the light emitting diode ED, and a third node N3 to which a driving voltage ELVDD is applied from a driving voltage line DVL. In the driving transistor DRT, the first node N1 is a gate node, the second node N2 may be a source node or a drain node, and the third node N3 may be a drain node or a source node.

The light emitting diode ED may include a first electrode 121, an organic layer 122, and a second electrode 123. The first electrode 121 may be an anode electrode disposed in each sub pixel SP and is electrically connected to the second node N2 of the driving transistor DRT of each sub pixel SP. The second electrode 123 may be a cathode electrode which is commonly disposed in the plurality of sub pixels SP and may be applied with a ground voltage ELVSS.

The scan transistor SCT is controlled to be turned on or off by a scan signal SCAN which is a gate signal applied through the gate line GL and may be electrically connected between the first node N1 of the driving transistor DRT and the data line DL.

The storage capacitor Cst may be electrically connected between the first node N1 and the second node N2 of the driving transistor DRT.

As illustrated in FIG. 3, each sub pixel SP may have a 2T (transistor) 1C (capacitor) structure including two transistors DRT and SCT and one capacitor Cst and in some cases, may further include one or more transistors or further include one or more capacitors.

Each of the driving transistor DRT and the scan transistor SCT may be an n type transistor or a p type transistor.

Circuit elements (specifically, a light emitting diode ED) in each sub pixel SP are vulnerable to external moisture or oxygen. Therefore, an encapsulation layer ENCAP for suppressing the permeation of external moisture or oxygen into the circuit elements (specifically, the light emitting diode ED) may be disposed on the display panel DP. The encapsulation layer ENCAP may be disposed so as to cover the light emitting diodes ED.

In the meantime, as one method for increasing a transmittance of at least one of the first optical area DA1 and the second optical area DA2, a pixel density differential design method may be applied.

According to the pixel density differential design method, the display panel DP may be designed such that the number of sub pixels per unit area of at least one of the first optical area DA1 and the second optical area DA2 is smaller than the number of sub pixels per unit area of the normal area NA.

In the meantime, in some cases, in contrast, as another method for increasing a transmittance of at least one of the first optical area DA1 and the second optical area DA2, a pixel size differential design method may be applied.

According to the pixel size differential design method, the display panel DP may be designed such that the number of sub pixels per unit area of at least one of the first optical area DA1 and the second optical area DA2 is equal to or similar to the number of sub pixels per unit area of the normal area NA. However, the size (that is, an emission area size) of each sub pixel SP disposed in at least one of the first optical area DA1 and the second optical area DA2 is smaller than the size (that is, an emission area size) of each sub pixel SP disposed in the normal area NA.

Hereinafter, for the convenience of description, it is assumed that the pixel density differential design method, between two methods (the pixel density differential design method and the pixel size differential design method) for increasing a transmittance of at least one of the first optical area DA1 and the second optical area DA2, is applied.

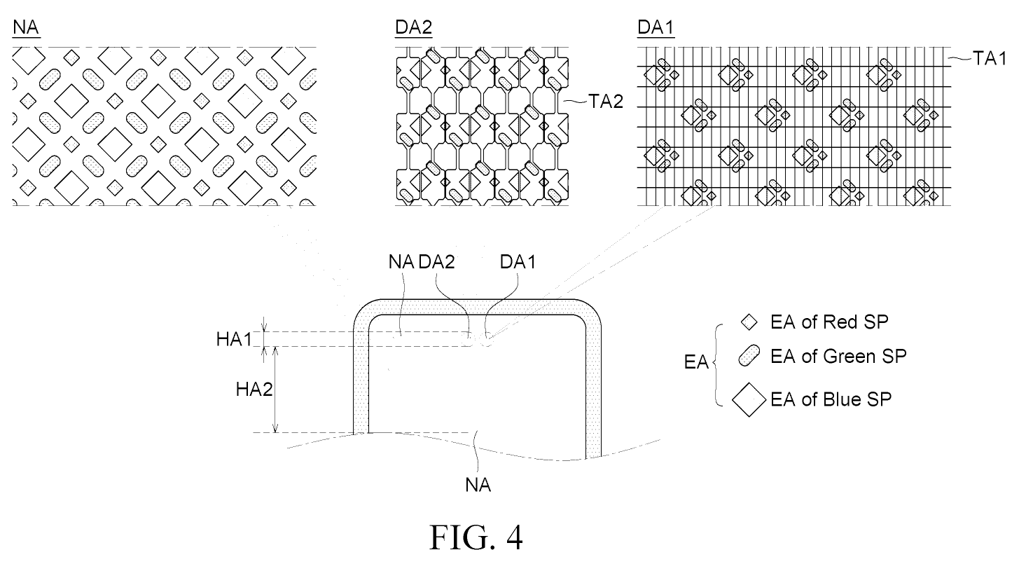

FIG. 4 is a view illustrating an example that a sub pixel of a display area according to an example embodiment of the present disclosure is disposed.

FIG. 4 illustrates the placement of the sub pixels SP in three areas NA, DA1, and DA2 included in the display area DA of the display panel according to the example embodiment of the present disclosure.

Referring to FIG. 4, in the normal area NA, the first optical area DA1, and the second optical area DA2 included in the display area, a plurality of sub pixels SP may be disposed.

For example, the plurality of sub pixels SP may include a red sub pixel Red SP which emits red light, a green sub pixel Green SP which emits green light, and a blue sub pixel Blue SP which emits blue light.

Therefore, each of the normal area NA, the first optical area DA1, and the second optical area DA2 may include an emission area EA of the red sub pixel Red SP, an emission area EA of the green sub pixel Green SP, and an emission area EA of the blue sub pixel Blue SP.

In FIG. 4, even though it is illustrated that emission areas EA of a plurality of green sub pixels green SP have different directions, the present disclosure is not limited thereto. For example, all the emission areas EA of the plurality of green sub pixels green SP may have the same direction.

Referring to FIG. 4, the normal area NA does not include a light transmission structure, but may include an emission area EA.

In contrast, the first optical area DA1 and the second optical area DA2 include not only the emission area EA, but also the light transmission structure.

Accordingly, the first optical area DA1 may include the emission area EA and a first transmissive area TA1, and the second optical area DA2 may include the emission area EA and a second transmissive area TA2.

The emission area EA and the transmissive areas TA1 and TA2 may be distinguished depending on how much light is transmissible. For example, the emission area EA is an area having a smaller amount of transmitted light than the transmissive areas TA1 and TA2.

Further, the emission area EA and the transmissive areas TA1 and TA2 may be distinguished depending on whether a specific metal layer is formed. Further, in the emission area EA, a light shielding layer (if the light shielding layer is a metal layer) is formed, and in the transmissive areas TA1 and TA2, the light shielding layer is not formed.

The first optical area DA1 includes a first transmissive area TA1 and the second optical area DA2 includes a second transmissive area TA2 so that light may pass through both the first optical area DA1 and the second optical area DA2.

A transmittance (degree of transmission) of the first optical area DA1 and a transmittance (a degree of transmission) of the second optical area DA2 may be equal.

In this case, the first transmissive area TA1 of the first optical area DA1 and the second transmissive area TA2 of the second optical area DA2 may have the same shape or same size. Alternatively, even though the first transmissive area TA1 of the first optical area DA1 and the second transmissive area TA2 of the second optical area DA2 have different shapes or sizes, a ratio of the first transmissive area TA1 in the first optical area DA1 and a ratio of the second transmissive area TA2 in the second optical area DA2 may be equal.

In contrast, a transmittance (a degree of transmission) of the first optical area DA1 and a transmittance (a degree of transmission) of the second optical area DA2 may be different from each other.

In this case, the first transmissive area TA1 of the first optical area DA1 and the second transmissive area TA2 of the second optical area DA2 may have different shapes or sizes. Alternatively, even though the first transmissive area TA1 of the first optical area DA1 and the second transmissive area TA2 of the second optical area DA2 have the same shape or size, a ratio of the first transmissive area TA1 in the first optical area DA1 and a ratio of the second transmissive area TA2 in the second optical area DA2 may be different.

For example, when the first optical electronic device which overlaps the first optical area DA1 is a camera and the second optical electronic device which overlaps the second optical area DA2 is a sensing sensor, the camera may require an amount of light larger than that of the sensing sensor.

Accordingly, the transmittance (a degree of transmission) of the first optical area DA1 may be higher than the transmittance (a degree of transmission) of the second optical area DA2.

In this case, the size of the first transmissive area TA1 of the first optical area DA1 may be larger than the size of the second transmissive area TA2 of the second optical area DA2. Alternatively, even though the first transmissive area TA1 of the first optical area DA1 and the second transmissive area TA2 of the second optical area DA2 have the same size, a percentage of the first transmissive area TA1 in the first optical area DA1 may be higher than a percentage of the second transmissive area TA2 in the second optical area DA2.

Hereinafter, for the convenience of description, an example that the transmittance (a degree of transmission) of the first optical area DA1 is higher than the transmittance (a degree of transmission) of the second optical area DA2 will be described.

In the example embodiment of the present disclosure, the transmissive areas TA1 and TA2 illustrated in FIG. 4 may also be referred to as transparent areas, and the transmittance may also be referred to as a transparency.

In the example embodiment of the present disclosure, as illustrated in FIG. 4, it is assumed that the first optical area DA1 and the second optical area DA2 are located in an upper end of the display area of the display panel and are horizontally parallel to each other.

Referring to FIG. 4, a horizontal display area in which the first optical area DA1 and the second optical area DA2 are disposed is referred to as a first horizontal display area HA1. Further, a horizontal display area in which the first optical area DA1 and the second optical area DA2 are not disposed is referred to as a second horizontal display area HA2.

The first horizontal display area HA1 may include the normal area NA, the first optical area DA1, and the second optical area DA2. In contrast, the second horizontal display area HA2 may include only the normal area NA.

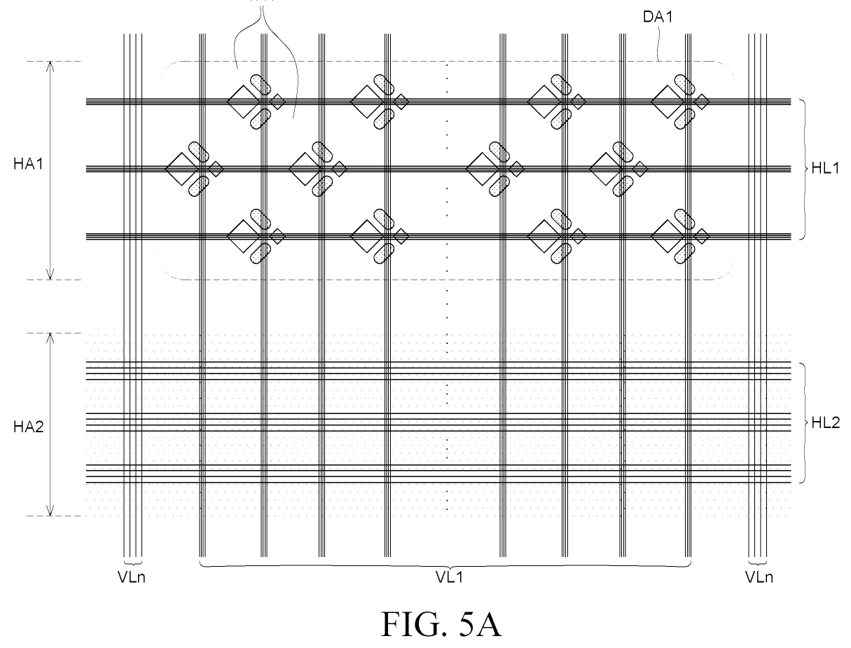

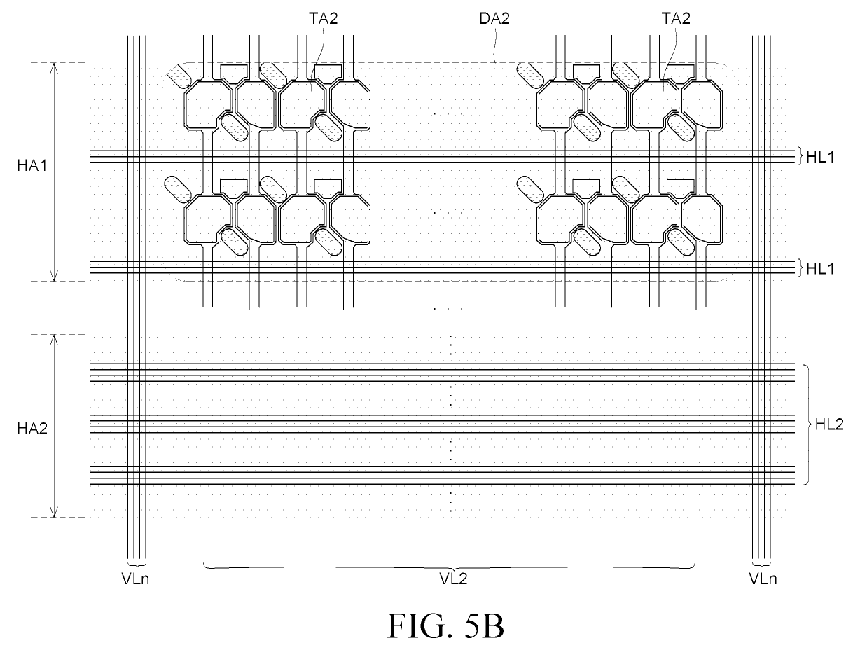

FIG. 5A is a view illustrating an example that a signal line is disposed in each of a first optical area and a normal area according to an example embodiment of the present disclosure.

FIG. 5B is a view illustrating an example that a signal line is disposed in each of a second optical area and a normal area according to an example embodiment of the present disclosure.

FIG. 5A illustrates the placement of the signal line in each of the first optical area DA1 and the normal area NA in the display panel DP according to the example embodiment of the present disclosure. FIG. 5B illustrates the placement of the signal line in each of the second optical area DA2 and the normal area NA in the display panel DP according to the example embodiment of the present disclosure.

In FIG. 5A, a part of the first horizontal display area HA1, a part of the second horizontal display area HA2, and a part of the first optical area DA1 are illustrated. In FIG. 5B, a part of the first horizontal display area HA1, a part of the second horizontal display area HA2, and a part of the second optical area DA2 are illustrated. Further, as illustrated in FIGS. 5A and 5B, the first horizontal display area HA1 includes the normal area, the first optical area DA1, and the second optical area DA2, and the second horizontal display area HA2 may include the normal area.

In the display panel DP, various types of horizontal lines HL1 and HL2 and vertical lines VLn, VL1, and VL2 may be disposed.

In the example embodiment of the present disclosure, the horizontal direction and the vertical direction refer to two intersecting directions, and the horizontal direction and the vertical direction may vary according to a viewing direction. For example, in the example embodiment of the present disclosure, the horizontal direction refers to a direction in which one gate line extends to be disposed, and the vertical direction refers to a direction in which one data line extends to be disposed.

Referring to FIGS. 5A and 5B, the horizontal line disposed in the display panel DP may include a first horizontal line HL1 disposed in the first horizontal display area HA1 and a second horizontal line HL2 disposed in the second horizontal display area HA2. At this time, the first horizontal line HL1 and the second horizontal line HL2 may be gate lines. The gate line may include various types of gate lines depending on the structure of the sub pixel.

Referring to FIGS. 5A and 5B, the vertical line disposed in the display panel DP may include a normal vertical line VLn disposed only in the normal area, a first vertical line VL1 which passes through both the first optical area DA1 and the normal area, and a second vertical line VL2 which passes through both the second optical area DA2 and the normal area.

Referring to FIGS. 4 and 5A, the first optical area DA1 included in the first horizontal area HA1 may include an emission area EA and a first transmissive area TA1. In the first optical area DA1, an outside area of the first transmissive area TA1 may include the emission area EA.

Referring to FIG. 5A, in order to improve the transmittance of the first optical area DA1, the first horizontal line HL1 which passes through the first optical area DA1 may pass while avoiding the first transmissive area TA1 in the first optical area DA1. Accordingly, each of the first horizontal lines HL1 which pass through the first optical area DA1 may include a curved section or a bending section which detours outside of an outer edge of the first transmissive area TA1.

Further, in order to improve the transmittance of the first optical area DA1, the first vertical line VL1 which passes through the first optical area DA1 may pass while avoiding the first transmissive area TA1 in the first optical area DA1. Accordingly, each of the first vertical lines VL1 which pass through the first optical area DA1 may include a curved section or a bending section which detours outside of an outer edge of the first transmissive area TA1.

Referring to FIG. 5A, the emission area may be disposed between two first transmissive areas TA1 which are adjacent to each other in the left and right in the first optical area DA1 in the first horizontal area HA1. The emission area may be disposed between two first transmissive areas which are adjacent to each other up and down in the first optical area DA1 in the first horizontal area HA1.

Referring to FIGS. 4 and 5B, the second optical area DA2 included in the first horizontal area HA1 may include an emission area EA and a second transmissive area TA2. In the second optical area DA2, an outside area of the second transmissive area TA2 may include the emission area EA.

As illustrated in FIG. 5B, the location and the placement state of the emission area EA and the second transmissive area TA2 in the second optical area DA2 may be different from the location and the placement state of the emission area EA and the first transmissive area TA1 in the first optical area DA1 in FIG. 5A.

However, in another example, the location and the placement state of the emission area EA and the second transmissive area TA2 in the second optical area DA2 may be equal to the location and the placement state of the emission area EA and the first transmissive area TA1 in the first optical area DA1 in FIG. 5A.

Further, in order to improve the transmittance of the second optical area DA2, the second vertical line VL2 which passes through the second optical area DA2 may pass while avoiding the second transmissive area TA2 in the second optical area DA2. As illustrated in FIG. 5B, the second vertical line VL2 which passes through the second optical area DA2 may include a curved section or a bending section which detours outside an outer edge of the second transmissive area TA2. Accordingly, the second vertical line VL2, which passes through the second optical area DA2, and the normal vertical line VLn, which does not pass through the second optical area DA2 and is disposed in the normal area, may have different shapes or lengths.

The first optical area DA1 which at least partially overlaps the first optical electronic device 170a includes a plurality of first transmissive areas TA1, and the second optical area DA2 which at least partially overlaps the second optical electronic device 170b includes a plurality of second transmissive areas TA2. Therefore, the number of sub pixels connected to the first horizontal line HL1 which passes through the first optical area DA1 and the second optical area DA2 is different from the number of sub pixels connected to the second horizontal line HL2 which does not pass through the first optical area DA1 and the second optical area DA2, but is disposed only in the normal area NA.

That is, the first optical area DA1 and the second optical area DA2 may have the number of sub pixels per unit area smaller than that of the normal area NA.

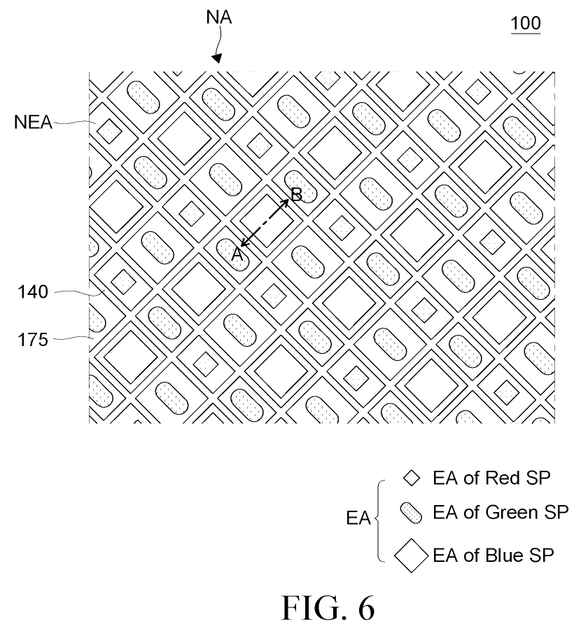

Hereinafter, a planar structure of the normal area NA and the first optical area DA1 of the display device 100 according to the example embodiment of the present disclosure will be described in detail with reference to FIG. 6.

FIG. 6 is a plan view schematically illustrating a normal area of a display device according to an example embodiment of the present disclosure.

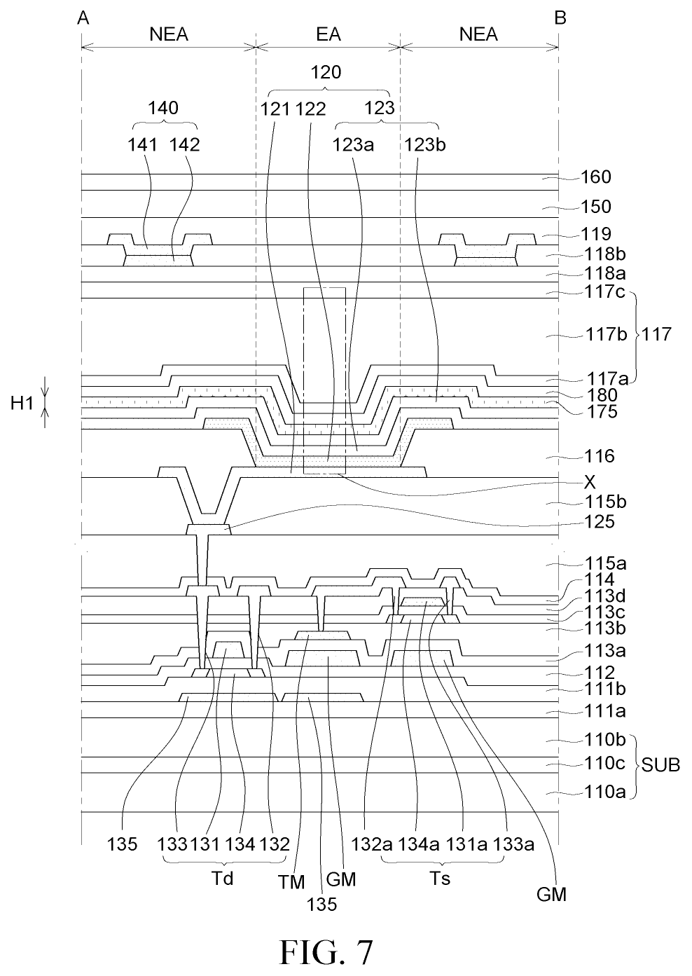

FIG. 7 is a cross-sectional view taken along A-B of FIG. 6.

Referring to FIGS. 6 and 7, the display device 100 may include a normal area NA.

The normal area NA may include a plurality of emission areas EA and a non-emission area which encloses the plurality of emission areas EA.

The plurality of emission areas EA may include an emission area EA of a red sub pixel Red SP, an emission area EA of a green sub pixel Green SP, and an emission area EA of a blue sub pixel Blue SP.

The plurality of emission areas EA disposed in the normal area NA and the first optical area DA1 may be disposed to be spaced apart from each other.

At least two emission areas EA of the emission area EA of a red sub pixel Red SP, the emission area EA of a green sub pixel Green SP, and the emission area EA of a blue sub pixel Blue SP may have different shapes and areas.

For example, the emission area EA of a red sub pixel Red SP and the emission area EA of a blue sub pixel Blue SP may have a quadrangular shape on the planar surface and the emission area EA of a green sub pixel Green SP may have an oval shape on the planar surface. However, the shapes of the plurality of emission areas EA are not limited thereto.

Further, an area of the emission area EA of one blue sub pixel Blue SP may be larger than an area of each of the emission area EA of one red sub pixel Red SP and the emission area EA of one green sub pixel Green SP. An area of the emission area EA of one green sub pixel Green SP may be larger than the emission area EA of one red sub pixel Red SP. However, the areas of the plurality of emission areas EA are not limited thereto.

The plurality of emission areas EA disposed in the normal area may be disposed to be spaced apart from each other.

Among the plurality of emission areas EA disposed in the normal area NA, emission areas EA disposed in n-th rows may be emission areas EA of a plurality of blue sub pixels Blue SP and emission areas EA of a plurality of red sub pixels Red SP. The emission area EA of a blue sub pixels Blue SP and the emission area EA of a red sub pixel Red SP disposed in each n-th row may be alternately disposed. Here, n may be an odd integer of 1 or larger (e.g., n may be 1, 3, 5, etc.). In another equivalent example, n may be an even integer of 0 or larger (e.g., n may be 0, 2, 4, etc.).

Further, emission areas EA disposed in n+1-th rows, among the plurality of emission areas EA disposed in the normal area NA may be emission areas EA of the plurality of green sub pixels Green SP. Each of the emission areas EA of the plurality of green sub pixels Green SP disposed in the n+1-th row may be disposed in an area between the emission areas EA of the plurality of blue sub pixels Blue SP and the emission areas EA of the plurality of red sub pixels Red SP disposed in the n-th row.

The plurality of emission areas EA disposed in the normal area NA may have a structure in which n-th row placement and n+1-th row placement are alternately disposed. In an example, the emission areas EA of the plurality of blue sub pixels Blue SP and the emission areas EA of the plurality of red sub pixels Red SP are disposed in odd-numbered rows; and the emission areas EA of the plurality of green sub pixels Green SP are disposed in even-numbered rows. In another equivalent example, the emission areas EA of the plurality of blue sub pixels Blue SP and the emission areas EA of the plurality of red sub pixels Red SP are disposed in even-numbered rows; and the emission areas EA of the plurality of green sub pixels Green SP are disposed in odd-numbered rows.

A touch electrode 140 may be disposed in the non-emission area NEA of the normal area NA.

The touch electrodes 140 are disposed between the plurality of sub pixels SP and intersect each other to have a mesh pattern. Accordingly, a user’s touch input may be sensed on top surfaces of the plurality of sub pixels SP disposed in the normal area.

A first deposition stop layer 175 may be disposed in the plurality of emission areas EA and the non-emission area NEA of the normal area NA.

The first deposition stop layer 175 may serve so as not to form the second electrode 123 during a process of forming the second electrode 123 of the light emitting diode 120.

In the normal area NA of the display device 100, a plurality of transistors Td and Ts, a light emitting diode 120, an encapsulation layer 117, and a plurality of touch electrodes 140 may be disposed on the substrate SUB.

In FIG. 7, an emission area EA of a green sub pixel Green SP, among a plurality of emission areas disposed in the normal area NA is illustrated as an example. However, sub pixels SP which emit light with different colors also have the same overall structure, except for light emitted from an emission stack which configures the light emitting diode 120.

The substrate SUB is a component for supporting various components included in the organic light emitting display device 100 and may be formed of an insulating material. The substrate SUB may include a first substrate 110a, a second substrate 110b, and an interlayer insulating film 110c. The interlayer insulating film 110c may be disposed between the first substrate 110a and the second substrate 110b.

As described above, the substrate SUB is configured by the first substrate 110a, the second substrate 110b, and the interlayer insulating film 110c to suppress the moisture permeation. For example, the first substrate 110a and the second substrate 110b may be polyimide (PI) substrates.

In the normal area NA, on substrate SUB, various patterns 131, 132, 133, 134, 131a, 132a, 133a, and 134a, various insulating films 111a, 111b, 112, 113a, 113b, and 114, and various metal patterns TM, GM, and 135 for forming a thin film transistor, such as a driving transistor Td and at least one switching transistor Ts and at least one capacitor, may be disposed.

Specifically, the multi-buffer layer 111a is disposed on the second substrate 110b and an active buffer layer 111b may be disposed on the multi-buffer layer 111a.

Each of the multi-buffer layer 111a and the active buffer layer 111b may be formed of a single layer of silicon nitride (SiNx) or silicon oxide (SiOx) or a plurality of layers of silicon nitride (SiNx) and silicon oxide (SiOx), but are not limited thereto.

A metal layer 135 may be disposed on the multi-buffer layer 111a.

Here, the metal layer 135 may serve as a light shield and is also referred to as a light shielding layer. The metal layer 135 may be any one of molybdenum (Mo), aluminum (Al), chrome (Cr), gold (Au), titanium (Ti), nickel (Ni), neodymium (Nd), and copper (Cu) or an alloy of two or more of them, or a plurality of layers thereof, but it is not limited thereto.

The active buffer layer 111b may be disposed on the metal layer 135.

A first active layer 134 of the driving transistor Td may be disposed on the active buffer layer 111b. The first active layer 134 may be formed of polycrystalline silicon (p-Si), amorphous silicon (a-Si), or oxide semiconductor, but is not limited thereto.

In the meantime, the driving transistor Td may include a first active layer 134, a first gate insulating film 112, a first gate electrode 131, a first interlayer insulating film 113a, a second gate insulating film 113c, a third interlayer insulating film 113d, and a first source electrode 132 and a first drain electrode 133. The first active layer 134 is formed on the active buffer layer 111b, the first gate insulating film 112 covers the first active layer 134, the first gate electrode 131 is disposed on the first gate insulating film 112, and the first interlayer insulating film 113a covers the first gate electrode 131. The second gate insulating film 113c is disposed on the first interlayer insulating film 113a, the third interlayer insulating film 113d is disposed on the second gate insulating film 113c, and the first source electrode 132 and the first drain electrode 133 are disposed on the third interlayer insulating film 113d.

The first gate insulating film 112 may be disposed on the first active layer 134. The first gate insulating film 112 may be formed by a single layer of silicon nitride (SiNx) or silicon oxide (SiOx) or a double layer of silicon nitride (SiNx) or silicon oxide (SiOx).

The first gate electrode 131 of the driving transistor Td may be disposed on the first gate insulating film 112. The first gate electrode 131 may be disposed on the first gate insulating layer 112 so as to overlap the first active layer 134.

The first gate electrode 131 may be formed of various conductive materials, for example, magnesium (Mg), aluminum (Al), nickel (Ni), chrome (Cr), molybdenum (Mo), tungsten (W), gold (Au), or an alloy thereof, but is not limited thereto.

A gate material layer GM may be disposed on the first gate insulating layer 112 in a position different from a forming position of the driving transistor Td.

A first interlayer insulating film 113a may be disposed on the first gate electrode 131 and the gate material layer GM.

A metal pattern TM may be disposed on the first interlayer insulating layer 113a.

The second interlayer insulating film 113b may be disposed while covering the metal pattern TM disposed on the first interlayer insulating film 113a.

The second interlayer insulating film 113b may serve to separate the second active layer 134a from the first active layer 134.

A second active layer 134a of the switching transistor Ts may be disposed on the second interlayer insulating film 113b. For example, the second active layer 134a may be formed of polycrystalline silicon (p-Si), amorphous silicon (a-Si), or oxide semiconductor, but is not limited thereto.

The second gate insulating film 113c may be disposed on the second active layer 134a.

Further, a second gate electrode 131a of the switching transistor Ts may be disposed on the second gate insulating film 113c. The second gate electrode 131a is disposed on the second gate insulating film 113c so as to overlap the second active layer 134a.

The second gate insulating film 113c covers the second active layer 134a of the switching transistor Ts. The second gate insulating film 113c is formed on the second active layer 134a so that the second gate insulating film may include an inorganic insulating material. For example, the second gate insulating film 113c may be formed by a single layer of silicon nitride (SiNx) or silicon oxide (SiOx) or a double layer of silicon nitride (SiNx) or silicon oxide (SiOx).

The second gate electrode 131a may include a metal material. For example, the second gate electrode 131a may be formed of a single layer or a plurality of layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

In the meantime, the switching transistor Ts is formed on the second interlayer insulating film 113b and may include a second active layer 134a, a second gate insulating film 113c which covers the second active layer 134a, a second gate electrode 131a disposed on the second gate insulating film 113c, a third interlayer insulating film 113d which covers the second gate electrode 131a, and a second source electrode 132a and a second drain electrode 133a disposed on the third interlayer insulating film 113d.

The switching transistor Ts may further include a gate material layer GM which is located below the first interlayer insulating film 113a and overlaps the second active layer 134a. The gate material layer GM blocks light which is incident onto the second active layer 134a to ensure the reliability of the switching transistor Ts.

The gate material layer GM is formed by the same material as the first gate electrode 131 and may be formed on an upper surface of the first gate insulating film 112. The gate material layer GM is electrically connected to the second gate electrode 131a to configure a dual gate.

The first source electrode 132 and the first drain electrode 133 of the driving transistor Td and the second source electrode 132a and the second drain electrode 133a of the switching transistor Ts may be disposed on the third interlayer insulating film 113d.

The second source electrode 132a and the second drain electrode 133a are simultaneously formed of the same material as the first source electrode 132 and the first drain electrode 133 on the third interlayer insulating film 113d to reduce the number of mask processes.

The first source electrode 132 and the first drain electrode 133 may be connected to one side and the other side of the first active layer 134 through contact holes formed in the third interlayer insulating film 113d, the second gate insulating film 113c, the second interlayer insulating film 113b, the first interlayer insulating film 113a, and the first gate insulating film 112.

The second source electrode 132a and the second drain electrode 133a may be connected to one side and the other side of the second active layer 134a through contact holes formed in the third interlayer insulating film 113d and the second gate insulating film 113c.

The first source electrode 132 and the first drain electrode 133 and the second source electrode 132a and the second drain electrode 133a may be a single layer or a plurality of layers formed of various conductive materials, for example, magnesium (Mg), aluminum (Al), nickel (Ni), chrome (Cr), molybdenum (Mo), tungsten (W), gold (Au), or an alloy thereof, but are not limited thereto.

A part of the first active layer 134 which overlaps the first gate electrode 131 is a channel region. One of the first source electrode 132 and the first drain electrode 133 is connected to one side of the channel region in the first active layer 134 and the other one is connected to the other side of the channel region in the first active layer 134.

The second active layer 134a may be configured with the same shape as the first active layer 134. When the second active layer 134a is implemented by an oxide semiconductor material, the second active layer 134a may include an intrinsic second channel region not doped with impurities, and a second source region and a second drain region doped with impurities to be conductive.

A passivation layer 114 may be disposed on the first source electrode 132 and the first drain electrode 133 and the second source electrode 132a and the second drain electrode 133a. The passivation layer 114 protects the driving transistor Td and may include an inorganic insulating material. For example, the passivation layer 114 may be formed as a single layer of silicon nitride (SiNx) or silicon oxide (SiOx) or a double layer of silicon nitride (SiNx) or silicon oxide (SiOx).

In the meantime, the gate material layer GM and the metal pattern TM are disposed on the first gate insulating film 112 so as to overlap to implement a capacitor Cst.

The metal pattern TM may be a single layer or a multilayer formed of any one of molybdenum (Mo), aluminum (Al), chrome (Cr), gold (Au), titanium (Ti), nickel (Ni), neodymium (Nd), and copper (Cu), or an alloy thereof, but is not limited thereto.

The capacitor Cst stores a data voltage which is applied through the data line DL for a predetermined period and then supplies the data voltage to the light emitting diode 120. The capacitor Cst may include two corresponding electrodes and a dielectric material disposed therebetween. The first interlayer insulating film 113a may be located between the gate material layer GM and the metal pattern TM.

The gate material layer GM or the metal pattern TM of the capacitor Cst may be electrically connected to the second source electrode 132a or the second drain electrode 133a of the switching transistor Ts. However, it is not limited thereto and a connection relationship of the capacitor Cst may vary according to the pixel driving circuit.

Further, the metal layer 135 is disposed on the multi-buffer layer 111a so as to further overlap the gate material layer GM and the metal pattern TM to configure a double capacitor Cst.

In the example embodiment of the present disclosure, at least one switching transistor Ts uses the oxide semiconductor as an active layer.

The transistor which uses the oxide semiconductor as an active layer has an excellent leakage current blocking effect and has a manufacturing cost which is relatively cheaper than the transistor which uses the polycrystalline silicon as an active layer. Accordingly, in order to reduce the power consumption and save the manufacturing cost, the pixel circuit according to the example embodiment of the present disclosure includes a driving transistor or at least one switching transistor which uses the oxide semiconductor material.

All the transistors which configure the pixel circuit including the driving transistor may implement the active layer using the oxide semiconductor or only some of the transistors may implement the active layer using the oxide semiconductor.

However, it is difficult for the transistor using the oxide semiconductor to ensure the reliability and the transistor using the polycrystalline silicon has a faster operation speed and excellent reliability. Accordingly, the example embodiment of the present disclosure includes all the transistor using the oxide semiconductor and the transistor using the polycrystalline silicon.

However, it is not limited thereto and in accordance with the design, only a transistor using the oxide semiconductor is applied or only a transistor using the polycrystalline silicon is applied to configure the pixel circuit.

A planarization layer which protects the driving transistor Td and planarizes an upper portion thereof may be disposed on the driving transistor Td.

The planarization layer may include a first planarization layer 115a and a second planarization layer 115b. The first planarization layer 115a may be disposed on the passivation layer 114 and a connection electrode 125 may be disposed on the first planarization layer 115a.

The connection electrode 125 may be connected to one of the first source electrode 132 and the first drain electrode 133 through a contact hole provided in the first planarization layer 115a.

The second planarization layer 115b may be disposed on the connection electrode 125.

The light emitting diode 120 may be located above the second planarization layer 115b.

The connection electrode 125 may be a single layer or a plurality of layers formed of any one of molybdenum (Mo), aluminum (Al), chrome (Cr), gold (Au), titanium (Ti), nickel (Ni), neodymium (Nd), and copper (Cu) or an alloy thereof, but is not limited thereto.

Each of the first planarization layer 115a and the second planarization layer 115b may include an organic insulating material. For example, the first planarization layer 115a and the second planarization layer 115b may be formed of one of acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

A first electrode 121 (or a 1-1-th electrode) of the light emitting diode 120 may be disposed on the second planarization layer 115b. At this time, the first electrode 121 may be electrically connected to the connection electrode 125 through the contact hole provided in the second planarization layer 115b.

The first electrode 121 may include a metallic material.

When the display device 100 according to the example embodiment of the present disclosure is a top emission type in which light emitted from the light emitting diode 120 is emitted toward a top layer on the substrate SUB (such as a polarization layer 160 in FIG. 7), the first electrode 121 may further include a transparent conductive layer and a reflective layer on the transparent conductor layer.

The transparent conductive layer may be formed of transparent conductive oxide, such as indium tin oxide (ITO) or indium zinc oxide (IZO) or indium gallium zinc oxide (IGZO) and the reflective layer may be formed of silver (Ag), aluminum (Al), gold (Au), molybdenum (Mo), tungsten (W), chrome (Cr), or an alloy thereof.

A bank 116 may be disposed to cover a part of an end portion of the first electrode 121 of the light emitting diode 120.

In an area of the sub pixel SP corresponding to the emission area EA, the bank 116 is not disposed. As another aspect, a hole (or an opening) of the bank 116 may be disposed in the emission area EA of the sub pixel SP.

The hole of the bank 116 may overlap a part of the first electrode 121. That is, a part of the first electrode 121 does not overlap the bank 116.

At this time, the bank 116 may be formed of an inorganic insulating material, such as silicon nitride (SiNx) or silicon oxide (SiOx), or an organic insulating material, such as benzocyclobutene-based resin, acrylic-based resin or imide-based resin, but is not limited thereto.

An organic layer 122 (or a first organic layer) of the light emitting diode 120 may be disposed in the hole of the bank 116 and therearound. Accordingly, the organic layer 122 may be disposed on the first electrode 121 exposed through the hole of the bank 116.

The organic layer 122 may include an emission layer and may further include at least one functional layer of a hole transport layer, a hole injection layer, an electron transport layer, and an electron injection layer in addition to an emission layer which emits specific color light. The organic layer 122 may include a plurality of organic films.

The second electrode 123 (or a 2-1-th electrode) of the light emitting diode 120 may be disposed on the organic layer 122.

As described above, the light emitting diode 120 may be formed by the first electrode 121, the organic layer 122, and the second electrode 123.

The second electrode 123 disposed in the normal area NA may be formed of a plurality of layers.

Specifically, the second electrode 123 of the light emitting diode 120 disposed in the normal area NA may include a first sub electrode 123a (or a 1-1-th sub electrode) disposed on the organic layer 122 and a second sub electrode 123b (or a 2-1-th sub electrode) disposed on the first sub electrode 123a.

Each of the first sub electrode 123a and the second sub electrode 123b of the second electrode 123 may be disposed in the entire normal area NA of the display device 100.

The first sub electrode 123a may include a material included in the electron injection layer.

Alternatively, each of the first sub electrode 123a and the second sub electrode 123b may include a transparent conductive material such as indium tin oxide (ITO) or indium zinc oxide (IZO), or a metal alloy such as MgAg or a ytterbium (Yb) alloy and may further include a metal doping layer, but is not limited thereto.

In the normal area NA, the first deposition stop layer 175 may be disposed on the second sub electrode 123b of the second electrode 123.

The first deposition stop layer 175 may include a non-metallic material. For example, the first deposition stop layer 175 may include an organic material.

The first deposition stop layer 175 may serve to suppress at least a part of the second electrode 123 from being deposited on the substrate SUB. In other words, in an area in which the first deposition stop layer 175 is disposed, the second electrode 123 may not be formed.

For example, the first deposition stop layer 175 may be deposited using a mask (fine metal mask, FMM) so as to correspond to the first transmissive area TA1. Specifically, after placing FMM so as to expose the transmissive area TA, the first deposition stop layer 175 may be formed.

In an area of the normal area NA in which the first deposition stop layer 175 is disposed, a third sub electrode of the second electrode 123 may not be disposed. The third sub electrode of the second electrode 123 is a configuration disposed in a partial area of the transmissive area TA, which will be described in further detail below.

As the first deposition stop layer 175 is disposed in the entire normal area NA, the third sub electrode of the second electrode 123 is not disposed so that the thickness of the second electrode 123 may be suppressed from being increased in the normal area NA.

When the thickness of the second electrode 123 is increased in the normal area NA, the transmittance is degraded so that a part of light emitted from the light emitting diode 120 is not escaped to the outside of the display device 100, which degrades the luminous efficiency of the display device 100.

However, the first deposition stop layer 175 is disposed in the entire normal area NA so that the thickness of the second electrode 123 is suppressed from being increased to suppress degradation of the luminance of the display device 100 in the normal area NA.

The first deposition stop layer 175 may be disposed in the emission area EA and the non-emission area NEA of the normal area NA.

The first deposition stop layer 175 may overlap the light emitting diode 120 in the emission area EA.

The first deposition stop layer 175 may overlap the plurality of touch electrodes 140 in the non-emission area NEA.

At least one capping layer 180 may be disposed on the first deposition stop layer 175. The capping layer 180 may include an organic capping layer or an inorganic capping layer and in some cases, may include at least one of the organic capping layer and the inorganic capping layer.

The encapsulation layer 117 may be disposed on the capping layer 180.

The encapsulation layer 117 may have a single layer structure or a multi-layered structure. For example, the encapsulation layer 117 may include a first encapsulation layer 117a, a second encapsulation layer 117b, and a third encapsulation layer 117c.

The first encapsulation layer 117a and the third encapsulation layer 117c are configured by inorganic films and the second encapsulation layer 117b may be configured by an organic film. Among the first encapsulation layer 117a, the second encapsulation layer 117b, and the third encapsulation layer 117c, the second encapsulation layer 117b is the thickest and may serve as a planarization layer.

The first encapsulation layer 117a is disposed on the second electrode 123 and may be disposed to be the most adjacent to the light emitting diode 120.

The first encapsulation layer 117a may be formed of an inorganic insulating material on which low-temperature deposition may be performed. For example, the first encapsulation layer 117a may be configured by silicon nitride (SiNx), silicon oxide (SiOx), silicon oxynitride (SiON), or aluminum oxide (Al2O3). The first encapsulation layer 117a is deposited under a low temperature atmosphere so that during the deposition process, the damage of the organic layer 122 of the light emitting diode 120 including an organic material which is vulnerable to the high temperature atmosphere may be suppressed.

The second encapsulation layer 117b may be formed of an organic insulating material, such as acrylic resin, epoxy resin, polyimide, polyethylene, or silicon oxy carbon (SiOC). For example, the second encapsulation layer 117b may be formed by an inkjet method, but is not limited thereto.

Even though it is not illustrated, a color filter may be disposed on the encapsulation layer 117.

Further, even though it is not illustrated in the drawing, in the non-display area NDA, a structure which blocks the flow of the second encapsulation layer 117b which configures the encapsulation layer 117 may be disposed. In order to suppress the collapse of the encapsulation layer 117, one or more structures may be disposed at an end portion of the inclined surface of the encapsulation layer 117 or therearound.

One or more structures may be disposed in a boundary of the display area DA and the non-display area NDA or in the vicinity of the boundary. The structure may be formed of one or more layers formed of an organic material, and for example, may include a lower layer formed of the same material on the same layer as the second planarization layer 115b and an upper layer formed of the same material on the same layer as the bank 116, but is not limited thereto.

The third encapsulation layer 117c may be formed above the substrate SUB on which the second encapsulation layer 117b is formed so as to cover upper surfaces and side surfaces of the second encapsulation layer 117b and the first encapsulation layer 117a.

At this time, the third encapsulation layer 117c may minimize or block the permeation of external moisture or oxygen into the first encapsulation layer 117a and the second encapsulation layer 117b. For example, the third encapsulation layer 117c may be configured by an inorganic insulating material, such as silicon nitride (SiNx), silicon oxide (SiOx), silicon oxynitride (SiON), or aluminum oxide (Al2O3).

A touch buffer film 118a is disposed on the encapsulation layer 117 and a touch electrode 140 may be disposed on the touch buffer film 118a.

The touch electrode 140 may include a touch sensor electrode 141 and a bridge electrode 142 located on different layers. A touch interlayer insulating film 118b may be disposed between the touch sensor electrode 141 and the bridge electrode 142.

For example, the touch sensor electrode 141 may include a first touch sensor electrode, a second touch sensor electrode, and a third touch sensor electrode which are disposed to be adjacent to each other.

For example, the first touch sensor electrode and the second touch sensor electrode are disposed in the first direction and the third touch sensor electrode may be disposed in a second direction intersecting the first touch sensor electrode and the second touch sensor electrode.

The first touch sensor electrode and the second touch sensor electrode are electrically connected. However, when there is the third touch sensor electrode disposed in the second direction intersecting the first direction between the first touch sensor electrode and the second touch sensor electrode disposed in the first direction, the first touch sensor electrode and the second touch sensor electrode may be electrically connected through the bridge electrode 142 on the different layer.

The bridge electrode 142 may be insulated from the third touch sensor electrode by the touch interlayer insulating film 118b.

In other words, in order to suppress the short-circuit of the plurality of touch electrodes disposed in the first direction and the second direction, in the intersecting area, the plurality of touch electrodes extending in the first direction may be electrically connected through the bridge electrode 142.

During the process of forming the touch electrode 140, chemicals (for example, developer or etchant) used for the process or moisture from the outside may be generated.

Therefore, the touch buffer film 118a is disposed and the touch electrode 140 is disposed thereon so that permeation of chemicals or moistures into the organic layer 122 of the light emitting diode 120 including an organic material during formation of the touch electrode 140 is suppressed to suppress the damage of the organic layer 122.

The touch buffer film 118a may be formed of an organic insulating material which is formed at a temperature lower than a predetermined temperature (for example, 100°C) to suppress the damage of the organic layer 122 of the light emitting diode 120 including an organic material which is vulnerable to a high temperature. The organic insulating material has a low permittivity of 1 to 3. For example, the touch buffer film 118a may be formed of acrylic, epoxy, or siloxane based material.

The protection layer 119 may be disposed so as to cover the plurality of touch electrodes 140, a touch routing line, and a ground line. The protection layer 119 may be configured by an organic insulating film.

The organic layer 150 may be disposed so as to cover the protection layer 119.

When only the protection layer 119 formed of the organic insulating film disposed on the uppermost layer of the display device 100, a step caused by the touch electrode 140 disposed below the protection layer 119 is not completely supplemented only with the protection layer 119. Therefore, there may be a problem in that a stain caused by the plurality of touch electrodes 140 is visible to the user. The organic layer 150 formed of an organic insulating film is added above the protection layer 119 to suppress the step on the uppermost layer of the display device 100, thereby improving the visibility.

The organic layer 150 may be formed of the same material as the second encapsulation layer 117b of the encapsulation layer 117 and for example, may be formed of an organic insulating material, such as acrylic resin, epoxy resin, polyimide, polyethylene, or silicon oxy carbon (SiOC). The organic layer 150 may be formed by the inkjet method, but is not limited thereto.

A polarization layer 160 may be disposed on the organic layer 150.

As in the display device 100 according to the example embodiment of the present disclosure, as described above, the first deposition stop layer 175 is disposed in the entire normal area NA, the third sub electrode of the second electrode 123 is not disposed. Therefore, the thickness of the second electrode 123 is suppressed from being increased in the normal area NA.

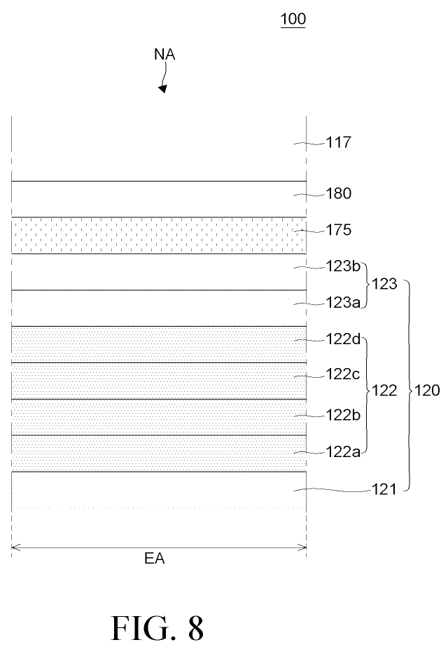

FIG. 8 is an enlarged view of an area X of FIG. 7.

Referring to FIG. 8, in the emission area EA of the normal area NA, the first electrode 121, the organic layer 122, the second electrode 123 of the light emitting diode 120, the first deposition stop layer 175, the capping layer 180, and the encapsulation layer 117 may be sequentially laminated.

The organic layer 122 may have a multi-layered structure. For example, the organic layer 122 may include at least one of a hole transport layer 122a, a hole injection layer 122b, an emission layer 122c, an electron transport layer 122d, and an electron injection layer.

The second electrode 123 may be disposed on the organic layer 122.

The second electrode 123 may include a first sub electrode 123a and a second sub electrode 123b in the normal area NA.

In the normal area NA, the first deposition stop layer 175 may be disposed on the second sub electrode 123b.

The capping layer 180 and the encapsulation layer 117 may be sequentially disposed on the first deposition stop layer 175.

In the display device 100 according to the example embodiment of the present disclosure, the first deposition stop layer 175 is disposed in the normal area NA so that the thickness of the second electrode 123 may be easily adjusted in the normal area NA. Accordingly, the degradation of the luminance of the display device 100 in the normal area NA due to the thickened second electrode 123 may be suppressed.

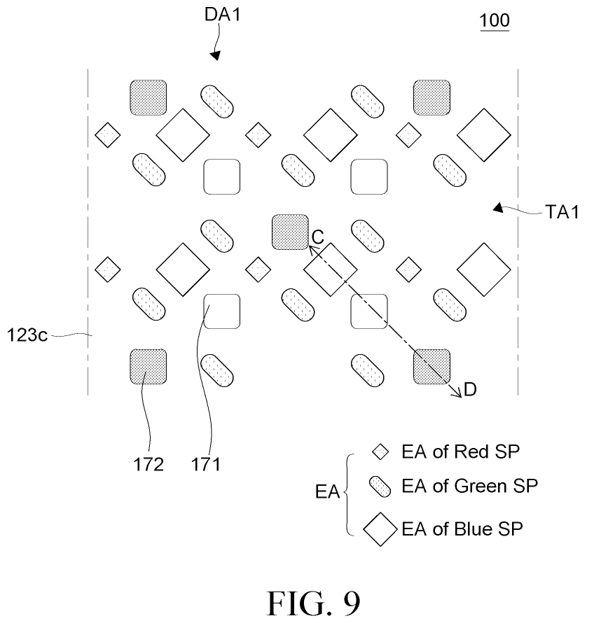

FIG. 9 is a plan view schematically illustrating a first optical area of a display device according to an example embodiment of the present disclosure.

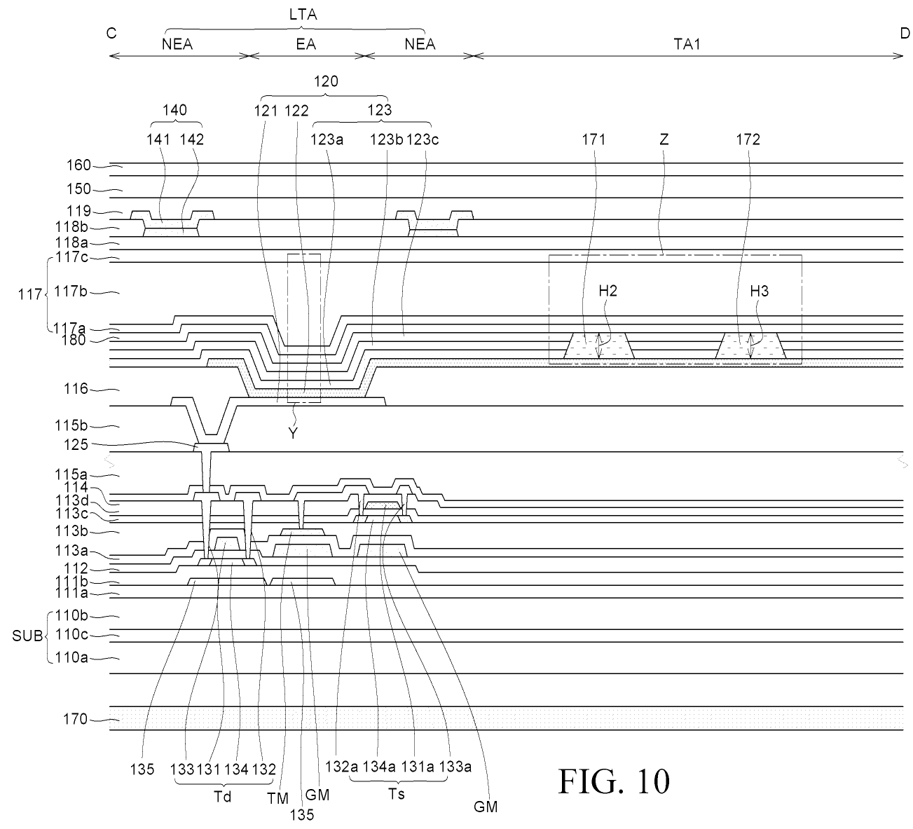

FIG. 10 is a cross-sectional view taken along the line C-D of FIG. 9.

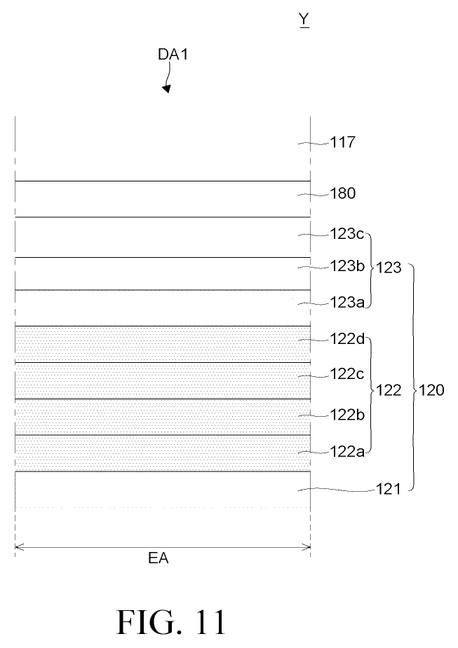

FIG. 11 is an enlarged view of an area Y of FIG. 10.

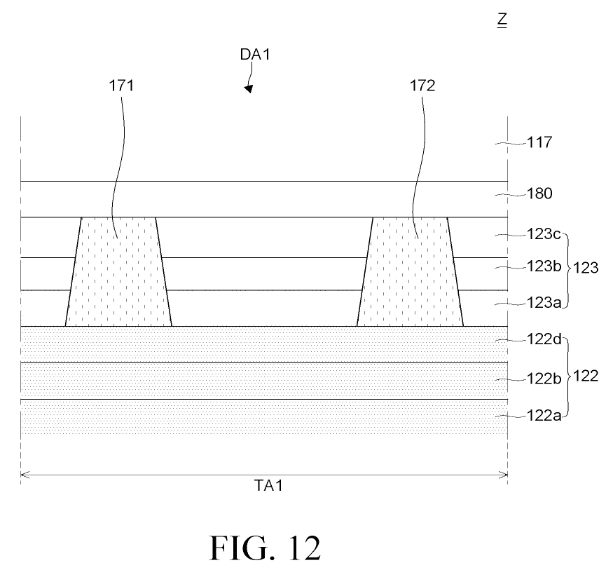

FIG. 12 is an enlarged view of an area Z of FIG. 10.

Hereinafter, for the convenience of description, an example that a display area DA of the display device 100 may include a normal area NA and a first optical area DA1 (that is, see FIGS. 1A and 1B) is described. In one or more aspects, the description for the first optical area DA1 may also be applied to the second optical area DA2 in the same way.

Referring to FIGS. 9 to 12, the first optical area DA1 may include a plurality of emission areas EA and a first transmissive area TA1.

The placement of the plurality of emission areas EA in the first optical area DA1 may be different from the placement of the plurality of emission areas EA in the normal area NA.

Specifically, emission areas EA disposed in n-th rows, among the plurality of emission areas EA disposed in the first optical area DA1, may be emission areas EA of the plurality of green sub pixels Green SP. Here, n may be an odd integer of 1 or larger. In another equivalent example, n may be an even integer of 0 or larger.

Among the plurality of emission areas EA disposed in the first optical area DA1, emission areas EA disposed in 4k-th rows may be emission areas EA of a plurality of blue sub pixels Blue SP and emission areas EA of a plurality of red sub pixels Red SP. The emission area EA of a blue sub pixel Blue SP and the emission areas EA of a red sub pixel Red SP disposed in each 4k-th row may be alternately disposed. Here, k may be an integer of 1 or larger. In another example, when n is an even integer of 0 or larger, 4k-th row is 4j-1-th row, where j may be an integer of 1 or larger.

The plurality of emission areas EA disposed in the first optical area DA1 may have a structure in which the placement of the n-th row and the placement of the 4kth row are repeated. In an example, the emission areas EA of the plurality of green sub pixels Green SP are disposed in odd-numbered rows; and the emission areas EA of the plurality of blue sub pixels Blue SP and the emission areas EA of the plurality of red sub pixels Red SP are disposed in a plurality of fourth rows not overlapping the odd-numbered rows. In another equivalent example, the emission areas EA of the plurality of green sub pixels Green SP are disposed in even-numbered rows; and the emission areas EA of the plurality of blue sub pixels Blue SP and the emission areas EA of the plurality of red sub pixels Red SP are disposed in a plurality of fourth rows not overlapping the even-numbered rows.

The density of the plurality of emission areas EA disposed in the first optical area DA1 may be lower than the density of the plurality of emission areas disposed in the normal area NA. For example, the density of the emission areas EA of the green sub pixels Green SP disposed in each n-th row of the first optical area DA1 may be lower than the density of the emission areas EA of the green sub pixels Green SP disposed in each n+1-th row of the normal area NA. In a further example, the emission areas EA of the plurality of blue sub pixels Blue SP and emission areas EA of the plurality of red sub pixels Red SP in the first optical area DA1 may be disposed in every fourth rows, instead of every two rows as seen in the normal area NA.

By doing this, an area of the first transmissive area TA1 of the first optical area DA1 is increased and the transmittance of the first optical area DA1 may be improved.

In FIGS. 9 to 12, an example that the placement of the plurality of emission areas EA of the normal area NA and the placement of the plurality of emission areas EA of the first optical area DA1 are different has been described. However, the placement of the emission area EA of the display device 100 according to the example embodiment of the present disclosure is not limited thereto. For example, the placement of the plurality of emission areas EA of the normal area NA and the placement of the plurality of emission areas EA of the first optical area DA1 may be the same.

Further, the area of each of the plurality of emission areas EA included in the first optical area DA1 and the area of each of the plurality of emission areas EA included in the normal area NA are equal to each other or are different from each other within a predetermined range.

At least one second deposition stop layer 171 and at least one third deposition stop layer 172 may be disposed in the first optical area DA1.

Specifically, at least one second deposition stop layer 171 and at least one third deposition stop layer 172 may be disposed in the first transmissive area TA1 of the first optical area DA1.

At least one second deposition stop layer 171 and at least one third deposition stop layer 172 may be disposed to be spaced apart from each other. Further, at least one second deposition stop layer 171 and at least one third deposition stop layer 172 are also disposed to be spaced apart from the plurality of emission areas EA disposed in the first optical area DA1.

The second deposition stop layer 171 and the third deposition stop layer 172 may include a non-metal material. For example, the second deposition stop layer 171 and the third deposition stop layer 172 may include an organic material.

The plurality of second deposition stop layers 171 and the plurality of third deposition stop layers 172 may be disposed on the same row as the emission area EA which emits at least one color light.

For example, a second deposition stop layer 171 is disposed between the emission areas EA of the green sub pixels Green SP disposed in every other n-th row, and a third deposition stop layer 172 may be disposed between the emission areas EA of the green sub pixels Green SP disposed in every other n-th row different from the rows occupied by a second deposition stop layer 171.

Further, each of one second deposition stop layer 171 and one third deposition stop layer 172 is disposed between two emission areas EA with respect to a row direction and may be disposed between two emission areas EA with respect to a column direction.

For example, one second deposition stop layer 171 is disposed between emission areas EA of different green sub pixels Green SP with respect to the row direction and may be disposed between emission areas EA of green sub pixels Green SP with respect to the column direction. Further, one third deposition stop layer 172 is disposed between emission areas EA of different green sub pixels Green SP with respect to the row direction and may be disposed between emission areas EA of green sub pixels Green SP with respect to the column direction.

Each of the second deposition stop layer 171 and the third deposition stop layer 172 is spaced apart from the emission area EA disposed in the first optical area DA1, is disposed between two emission areas EA with respect to the row direction, and is disposed between two emission areas EA with respect to the column direction. By doing this, the transmittance of the first optical area DA1 is improved and a performance of the optical electronic device 190 disposed in the first optical area DA1 may be improved.

For example, if a camera or an IR sensor is disposed in the first optical area DA1, the performance of the electronic device may be determined depending on an amount of light in a specific wavelength band which escapes out of the display device 100 in the first optical area DA1.

At this time, each of the second deposition stop layer 171 and the third deposition stop layer 172 is spaced apart from the emission area EA disposed in the first optical area DA1, disposed between two emission areas EA with respect to the row direction, and is disposed between two emission areas EA with respect to the column direction. By doing this, an amount of light in a specific wavelength band which is emitted to the outside of the display device 100 is increased to improve a performance of the optical electronic device 190 included in the display device 100.

The plurality of emission areas EA of the first optical area DA1 may be included in a low transmissive area LTA of the first optical area DA1.

In the first optical area DA1, in the low transmissive area LTA excluding the first transmissive area TA1, a plurality of light emitting diodes 120 for the plurality of emission areas EA may be disposed.

Further, a plurality of pixel circuits for driving the plurality of light emitting diodes 120 may be disposed in the low transmissive area LTA. That is, in the optical area OA, a plurality of pixel circuits may be disposed. The plurality of pixel circuits may include a driving transistor Td and a switching transistor Ts.

The low transmissive area LTA of the first optical area DA1 may include a part of the non-emission area NEA. The non-emission area NEA disposed in the low transmissive area LTA may include an area in which the plurality of pixel circuits is disposed, but is not limited thereto.

For example, a plurality of pixel circuits is not disposed in the first optical area DA1, but may be disposed in an additional bezel area which encloses an outer periphery of the first optical area DA1.

In the first optical area DA1, a transmittance of the low transmissive area LTA is lower than a transmittance of the first transmissive area TA1. However, the transmittance of the low transmissive area LTA in the first optical area DA1 may be higher than a transmittance of the normal area NA.

A low transmissive area LTA of the first optical area DA1 of FIG. 10 has a different structure of the second electrode 123 as compared with the normal area NA illustrated in FIG. 7, but other components are substantially the same so that a redundant description will be omitted.

The light emitting diode 120 disposed in the first optical area DA1 may include a first electrode 121 (or a 1-2-th electrode), an organic layer 122 (or a second organic layer), and a second electrode 123 (or a 2-2-th electrode).

The second electrode 123 of the light emitting diode 120 disposed in the first optical area DA1 may include a first sub electrode 123a (or a 1-2-th sub electrode) disposed on the organic layer 122, a second sub electrode 123b (or a 2-2-th sub electrode) disposed on the first sub electrode 123a, and a third sub electrode 123c disposed on the second sub electrode 123b.

The third sub electrode 123c may include a transparent conductive material such as indium tin oxide (ITO) or indium zinc oxide (IZO), or a metal alloy such as MgAg or a ytterbium (Yb) alloy and may further include a metal doping layer, but is not limited thereto.

The second electrode 123 of the light emitting diode 120 disposed in the normal area NA has a structure including the first sub electrode 123a and the second sub electrode 123b. The second electrode 123 of the light emitting diode 120 disposed in the first optical area DA1 may include the first sub electrode 123a, the second sub electrode 123b, and the third sub electrode 123c.

Specifically, the first sub electrode 123a and the second sub electrode 123b of the second electrode 123 are disposed in the normal area NA and the first optical area DA1, and the first deposition stop layer 175 may be disposed on the second sub electrode 123b of the normal area NA.

In contrast, the first deposition stop layer 175 is not disposed on the second sub electrode 123b in the low transmissive area LTA of the first optical area DA1 so that the third sub electrode 123c may be further disposed on the second sub electrode 123b.

The third sub electrode 123c is further disposed on the second sub electrode 123b in the low transmissive area LTA of the first optical area DA1. Therefore, a thickness of the second electrode 123 of the light emitting diode 120 disposed in the low transmissive area LTA of the first optical area DA1 may be greater than a thickness of the second electrode 123 of the light emitting diode 120 disposed in the normal area NA.

A thickness of the third sub electrode 123c may be 1 to 20 Å, but is not limited thereto.

The third sub electrode 123c of the second electrode 123 is further disposed in the low transmissive area LTA of the first optical area DA1 so that the second electrode 123 is thickened as much as the thickness of the third sub electrode 123c. Therefore, the micro cavity effect of the light emitting diode 120 disposed in the first optical area DA1 may be obtained.

Specifically, the thickness of the second electrode 123 of the light emitting diode 120 disposed in the first optical area DA1 is increased as much as a thickness of the third sub electrode 123c to increase the intensity of light emitted from the light emitting diode 120. By doing this, the luminance of the first optical area DA1 is increased.

The density of the emission area EA disposed in the first optical area DA1 is lower than the density of the emission area EA disposed in the normal area NA so that the luminance of the first optical area DA1 is lower than the luminance of the normal area NA. In order to cancel this problem, the luminance of the first optical area DA1 is increased by increasing the power consumption of the first optical area DA1. However, this leads to a problem in that when the display device 100 is driven, the power consumption is increased.

However, the thickness of the second electrode 123 of the light emitting diode 120 disposed in the first optical area DA1 makes thicker than the thickness of the second electrode 123 of the light emitting diode 120 disposed in the normal area NA. By doing this, the micro cavity effect of the first optical area DA1 may be induced and the luminance of the first optical area DA1 may be increased thereby.

Further, the luminance of the first optical area DA1 is increased by the micro cavity effect so that there is no need to increase the power consumption of the display device 100. Therefore, as compared with the display device 100 in which the second electrode 123 of the light emitting diode 120 disposed in the normal area NA and the second electrode 123 of the light emitting diode 120 disposed in the first optical area DA1 have the same structure, the display device 100 is driven with lower power consumption.

The substrate SUB and various insulating films 111a, 111b, 112, 113a, 113b, 114, 115a, 115b, 117a, 117b, 117c, 118a, 118b, and 119 disposed in the low transmissive area LTA of the first optical area DA1 may also be disposed in the first transmissive area TA1 of the first optical area DA1 in the same way.

In the meantime, in FIG. 10, a structure in which the bank 116 may be disposed so as to extend to the first transmissive area TA1 has been illustrated, but the present disclosure is not limited thereto. For example, the bank 116 is not disposed in the first transmissive area TA1, but may be disposed only in a partial area of the first transmissive area TA1.

In addition to an insulating material disposed in the low transmissive area LTA of the first optical area DA1, a material layer having an electrical characteristic or an opaque characteristic may not be disposed in the first transmissive area TA1 of the first optical area DA1.

For example, the metal material layers 131, 132, 133, 135, GM, TM, 131a, 132a, and 133a and the active layers 134 and 134a related to the transistors may not be disposed in the first transmissive area TA1.

Further, the touch electrode 140 is disposed in the low transmissive area LTA, but is not disposed in the first transmissive area TA1. Further, the touch electrode 140 may be disposed in the non-emission area NEA included in the low transmissive area LTA.

Further, the first electrode 121 included in the light emitting diode 120 may not be disposed in the first transmissive area TA1.

The first transmissive area TA1 of the first optical area DA1 overlaps the optical electronic device 190. Therefore, for the purpose of the normal operation of the optical electronic device 190, an opaque component, such as a metal electrode, is not disposed in the first transmissive area TA1 to increase the transmittance of the first transmissive area TA1.

Further, in the first transmissive area TA1 of the first optical area DA1, a component, such as a metal electrode, is not disposed so that the first transmissive area TA1 of the first optical area DA1 may be configured only by a layer with a flat top surface.

The organic layer 122 included in the light emitting diode 120 may be disposed in the first transmissive area TA1, but is not limited thereto. For example, the organic layer 122 included in the light emitting diode 120 is not disposed in the first transmissive area TA1, but may be disposed only in a partial area of the first transmissive area TA1.

For example, as illustrated in FIG. 11, in the first optical area DA1, at least one of a hole transport layer 122a, a hole injection layer 122b, an emission layer 122c, an electron transport layer 122d, and an electron injection layer included in the organic layer 122 may be disposed.

Specifically, in the low transmissive area LTA including the emission area EA of the first optical area DA1 and the non-emission area NEA adjacent to the emission area EA, the hole transport layer 122a, the hole injection layer 122b, the emission layer 122c, the electron transport layer 122d, and the electron injection layer of the organic layer 122 are disposed.

Further, as illustrated in FIG. 12, only some layers of the plurality of organic layers 122 included in the light emitting diode 120 may be disposed to extend to the first transmissive area TA1. For example, only remaining layers excluding the emission layer 122c, among the plurality of organic layers 122, are disposed in the first transmissive area TA1.

In order to ensure the transmittance of the first transmissive area TA1, if the second electrode 123 is removed, ultraviolet (UV) reliability of the first transmissive area TA1 may be degraded. That is, a pixel shrinkage defect occurs in which an effective emission area of the emission area EA is reduced due to outgassing of an organic material caused by the transmission of the ultraviolet ray.

The emission layer 122c of the organic layer 122 is not disposed in the first transmissive area TA1 so that a probability of a damage caused to the first transmissive area TA1 may be reduced. However, the position of the emission layer 122c according to the example embodiment of the present disclosure is not limited thereto.

Referring to FIGS. 9 to 12, the second electrode 123 of the light emitting diode 120 may be disposed only in a partial area of the first transmissive area TA1.

Specifically, in an area of the first transmissive area TA1 in which the second electrode 123 of the light emitting diode 120 is disposed, a first sub electrode 123a, a second sub electrode 123b, and a third sub electrode 123c of the second electrode 123 are sequentially laminated.

At least one second deposition stop layer 171 and at least one third deposition stop layer 173 may be disposed in the first transmissive area TA1.

The second deposition stop layer 171 and the third deposition stop layer 172 may be disposed on the same layer in the first transmissive area TA1. For example, the second deposition stop layer 171 and the third deposition stop layer 172 may be disposed on an organic layer 122.

The first sub electrode 123a, the second sub electrode 123b, and the third sub electrode 123c of the second electrode 123 may not be disposed in an area in which the second deposition stop layer 171 and the third deposition stop layer 172 are disposed.

The second deposition stop layer 171 and the third deposition stop layer 172 may serve to suppress the first sub electrode 123a, the second sub electrode 123b, and the third sub electrode 123c of the second electrode 123 from being deposited on the organic layer 122.

Accordingly, after forming the second deposition stop layer 171 and the third deposition stop layer 172 on the organic layer 122, if the first sub electrode 123a, the second sub electrode 123b, and the third sub electrode 123c of the second electrode 123 are sequentially formed, the first sub electrode 123a, the second sub electrode 123b, and the third sub electrode 123c of the second electrode 123 may not be disposed in an area in which the second deposition stop layer 171 is disposed and in an area in which the third deposition stop layer 172 is disposed.

Additionally, the first deposition stop layer 175 is disposed on the second sub electrode 123b of the second electrode 123 disposed in the normal area NA so that the third sub electrode 123c of the second electrode 123 is not deposited in the normal area NA (see FIG. 7).

A height H1 of the first deposition stop layer 175 disposed in the normal area NA may be lower than each of a height H2 of the second deposition stop layer 171 and a height H3 of the third deposition stop layer 172 disposed in the first transmissive area TA1 of the first optical area DA1.

Here, a height of the first deposition stop layer 175 may refer to the shortest length in a direction in which the first deposition stop layer 175 is disposed on the second sub electrode 123b in the normal area NA.

Further, a height of each of the second deposition stop layer 171 and the third deposition stop layer 172 may refer to the shortest length in a direction in which a respective one of the second deposition stop layer 171 and the third deposition stop layer 172 is disposed or laminated on the organic layer 122 in the first transmissive area TA1 of first optical area DA1.

In the meantime, in FIGS. 10 and 12, it is illustrated that each of the heights of the second deposition stop layer 171 and the third deposition stop layer 172 is equal to a sum of a height of the first sub electrode 123a, a height of the second sub electrode 123b, and a height of the third sub electrode 123c, but the present disclosure is not limited thereto. For example, each or at least one of the heights of the second deposition stop layer 171 and the third deposition stop layer 172 may be smaller than a sum of a height of the first sub electrode 123a, a height of the second sub electrode 123b, and a height of the third sub electrode 123c.

The second deposition stop layer 171 and the third deposition stop layer 172 may be deposited using a mask (fine metal mask, FMM) so as to correspond to the first transmissive area TA1.

The second deposition stop layer 171 and the third deposition stop layer 172 disposed in the first transmissive area TA1 may have different areas (or sizes) on the planar surface. However, the areas of the second deposition stop layer 171 and the third deposition stop layer 172 are not limited thereto.

Further, a shape of the second deposition stop layer 171 and the third deposition stop layer 172 may be a quadrangular shape on the planar surface, but is not limited thereto. For example, each of the second deposition stop layer 171 and the third deposition stop layer 172 may be formed to have any one of a circular shape, a semi-circular shape, an oval shape, or a polygonal shape on the planar surface.

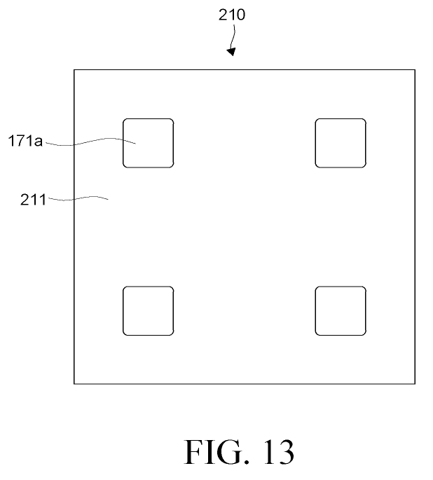

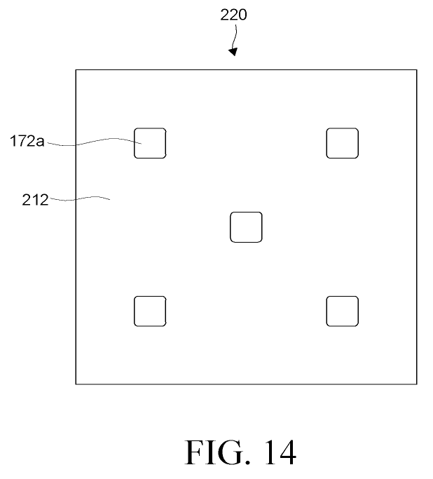

When the second deposition stop layer 171 and the third deposition stop layer 172 have different areas or shapes, the second deposition stop layer 171 and the third deposition stop layer 172 may be formed using different masks. A process for forming the second deposition stop layer 171 and the third deposition stop layer 172 will be described in more detail with reference to FIGS. 13 and 14.

An area of the second electrode 123 which is disposed in the first transmissive area TA1 is adjusted by adjusting areas and shapes of the second deposition stop layer 171 and the third deposition stop layer 172, thereby adjusting the transmittance of the first transmissive area TA1.

Specifically, in an example, it is assumed that a sum of a percentage of an area in which the second electrode 123 is disposed in the first optical area DA1, a percentage of an area in which the second deposition stop layer 171 is disposed in the first optical area DA1, and a percentage of an area in which the third deposition stop layer 172 is disposed in the first optical area DA1 is 100%. In this example, a percentage of an area in which the second deposition stop layer 171 and the third deposition stop layer 172 are disposed may be 4% to 26%. For example, a percentage of an area in which the second deposition stop layer 171 and the third deposition stop layer 172 are disposed may be 6.9% to 9.9%.

In other words, a percentage of an area in which the second electrode 123 is not disposed in the first optical area DA1 may be 4% to 26%.

If the percentage of an area in which the second electrode 123 is not disposed in the first optical area DA1 is less than 4%, the transmittance of the first transmissive area TA1 may be significantly degraded.

Further, if the percentage of an area in which the second electrode 123 is not disposed in the first optical area DA1 exceeds 26%, the UV reliability may be weakened. That is, outgassing of the organic material is caused by the transmission of the ultraviolet ray so that the pixel shrinkage defect of the emission unit may occur.

In other words, the second electrode 123 serves to improve the UV reliability of the first transmissive area TA1. A percentage of an area of the first transmissive area TA1 occupied by the second deposition stop layer 171 and the third deposition stop layer 172 is adjusted so that even though the second electrode 123 is not disposed in a partial area of the first transmissive area TA1, degradation of the UV reliability may be suppressed.

As described above, at least one second deposition stop layer 171 and at least one third deposition stop layer 172 are disposed in a part of the first transmissive area TA1 included in the first optical area DA1. Therefore, the second electrode 123 of the light emitting diode 120 may not be disposed in an area in which the second deposition stop layer 171 and the third deposition stop layer 172 are disposed. By doing this, the transmittance of the first transmissive area TA1 may be improved.

Further, in the remaining part of the first transmissive area TA1 of the first optical area DA1, the first sub electrode 123a, the second sub electrode 123b, and the third sub electrode 123c of the second electrode 123 of the light emitting diode 120 are sequentially laminated to improve the UV reliability of the first transmissive area TA1.

Further, the second electrode 123 of the light emitting diode 120 disposed in the low transmissive area LTA of the first optical area DA1 includes the third sub electrode 123c so that the luminous efficiency of the light emitting diode 120 may be improved by the micro cavity effect of the light emitting diode 120.

Accordingly, there is no need to increase the power consumption to improve the luminance of the first optical area DA1 having a density of the emission area EA lower than that of the normal area NA. Therefore, a high level of luminance characteristic may be maintained in the normal area NA and the first optical area DA1 even with a low power.

Next, a process of forming the second deposition stop layer 171 and the third deposition stop layer 172 of the display device 100 according to the example embodiment of the present disclosure will be described with reference to FIGS. 13 and 14 as follows.

FIG. 13 is a plan view schematically illustrating a mask used for forming a second deposition stop layer.

FIG. 14 is a plan view schematically illustrating a mask used for forming a third deposition stop layer.

Referring to FIGS. 13 and 14, a mask 210 (hereinafter, referred to as a first mask) used to form the second deposition stop layer 171 and a mask 220 (hereinafter, referred to as a second mask) used to form the third deposition stop layer 172 in the first transmissive area TA1 of the first optical area DA1 may be different masks.

In a first body 211 of the first mask 210, at least one first pattern 171a for forming the second deposition stop layer 171 may be prepared.

In a second body 212 of the second mask 220, at least one second pattern 172a for forming the third deposition stop layer 172 may be prepared.

The first pattern 171a and the second pattern 172a may have different sizes. However, the present disclosure is not limited thereto, and the first pattern 171a and the second pattern 172a may have the same size.

The first pattern 171a and the second pattern 172a may have a quadrangular shape on the planar surface. However, the present disclosure is not limited thereto and the shapes of the first pattern 171a and the second pattern 172a may be any one of a circle, a semi-circle, an oval, or a polygonal shape on the planar surface.

The second deposition stop layer 171 and the third deposition stop layer 172 may be disposed between the plurality of emission areas EA disposed in the first optical area DA1. In order to uniformly place the second deposition stop layer 171 and the third deposition stop layer 172 in a desired position with a desired size, a margin between the first pattern 171a and the second pattern 172a is necessary.

Patterns with the same size are uniformly disposed on the entire surface of the mask used to form the plurality of emission areas EA disposed in the first optical area DA1 so that it is easy to align positions of the mask and the substrate by pulling the mask up, down, left, and right.

In contrast, sizes or shapes of patterns of masks for forming the second deposition stop layer 171 and the third deposition stop layer 172 are different, and specifically, the first optical area DA1 in which the second deposition stop layer 171 and the third deposition stop layer 172 are disposed is disposed in an upper edge of the display device 100. Therefore, it is difficult to align the positions of the mask and the substrate by pulling the mask up, down, left, and right.

Accordingly, when the second deposition stop layer 171 and the third deposition stop layer 172 are formed, if different masks are used, the second deposition stop layer 171 and the third deposition stop layer 172 may be uniformly disposed in a desired position with a desired size.

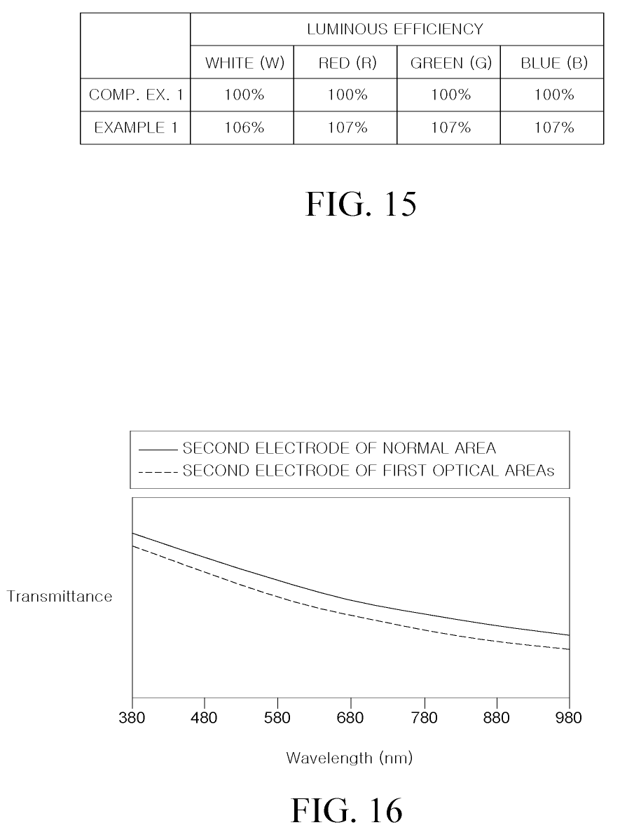

FIG. 15 is a table for comparing an efficiency of a light emitting diode of a display device according to Comparative Example 1 and an efficiency of a light emitting diode of a display device according to Example 1.

In FIG. 15, a light emitting diode of a display device according to Comparative Example 1 includes a first electrode, an organic layer, and a single-layered second electrode. A light emitting diode of a display device according to Example 1 has the same structure as the light emitting diode 120 disposed in the first optical area DA1 of FIG. 10.

Referring to FIG. 15, the light emitting diode of the display device according to Comparative Example 1 shows 100% of luminous efficiency for white W, red R, green G, and blue B.

In contrast, a light emitting diode of a display device according to Example 1 shows 106% of efficiency for white W, 107% of efficiency for red R, 107% of efficiency for green G, and 107% of efficiency for blue B. Therefore, it is understood that the luminous efficiency for all color light of the light emitting diode of Example 1 is higher than the efficiency of the light emitting diode of Comparative Example 1.

That is, in the display device according to the example embodiment of the present disclosure, the light emitting diode 120 disposed in the low transmissive area LTA of the first optical area DA1 includes a second electrode 123 including first to third sub electrodes 123a, 123b, and 123c to achieve the micro cavity effect. Therefore, a high luminous efficiency may be achieved without increasing the power consumption.

FIG. 16 is a graph for comparing a transmittance of a second electrode of a light emitting diode disposed in a normal area and a transmittance of a second electrode of a light emitting diode disposed in a first optical area of a display device according to an example embodiment of the present disclosure.

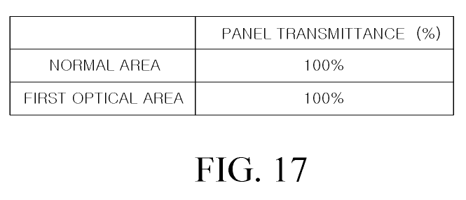

FIG. 17 is a table for comparing a panel transmittance of a normal area and a panel transmittance of a first optical area of a display device according to an example embodiment of the present disclosure.

Referring to FIGS. 16 and 17, it is understood that a transmittance of the second electrode 123 of the light emitting diode 120 disposed in the normal area NA is higher than a transmittance of the second electrode 123 of the light emitting diode 120 disposed in the first optical area DA1.

As compared with the second electrode 123 of the light emitting diode 120 disposed in the normal area NA, the second electrode 123 of the light emitting diode 120 disposed in the first optical area DA1 further includes the third sub electrode 123c. Therefore, a thickness of the second electrode 123 of the light emitting diode 120 disposed in the first optical area DA1 may be larger than a thickness of the second electrode 123 of the light emitting diode 120 disposed in the normal area NA.

By doing this, the second electrode 123 disposed in the normal area NA and the second electrode 123 disposed in the first optical area DA1 may have different transmittances.

However, as illustrated in FIG. 17, a panel transmittance of the first optical area DA1 to which a light emitting diode including a second electrode 123 further including the third sub electrode 123c is applied may be equal to a panel transmittance of the normal area NA to which a light emitting diode including a second electrode 123 which does not include a third sub electrode 123c is applied.

Even though the light emitting diode including the second electrode 123 including the third sub electrode 123c is disposed in the first optical area DA1 and the second electrode 123 including the third sub electrode 123c is disposed in a partial area of the first transmissive area TA1 of the first optical area DA1, the second deposition stop layer 171 and the third deposition stop layer 172 are disposed in the other partial area of the first transmissive area TA1. Therefore, there may be an area in which the second electrode 123 including the third sub electrode 123c is not disposed.

That is, there is an area in which the second electrode 123 including the third sub electrode 123c is not disposed, in the first transmissive area TA1 of the first optical area DA1. Therefore, even though the second electrode 123 including the third sub electrode 123c disposed in a partial area of the first optical area DA1, the panel transmittance of the first optical area DA1 may be improved.

The panel transmittance of the first optical area DA1 is equal to the panel transmittance of the normal area NA so that there is no need to increase the power consumption to increase an amount of light emitted from the first optical area DA1.

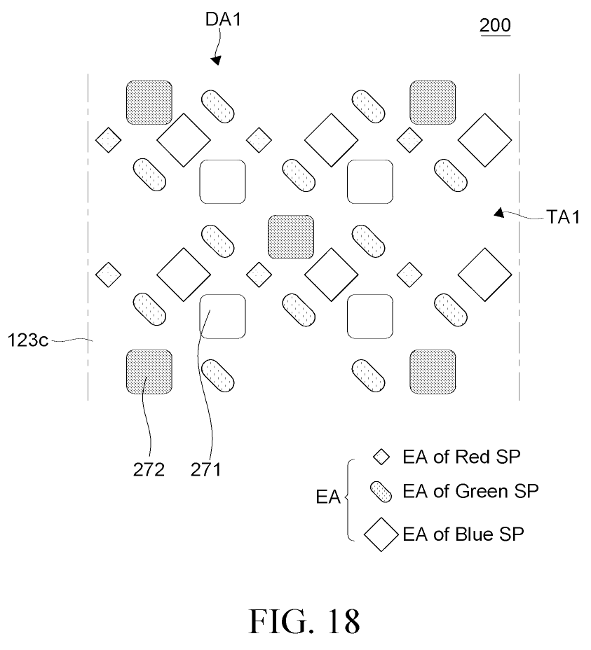

FIG. 18 is a plan view schematically illustrating a first optical area of a display device according to another example embodiment of the present disclosure.

A display device 200 of FIG. 18 is substantially the same as the display device 100 of FIG. 9 except for areas of a second deposition stop layer 271 and a third deposition stop layer 272, so that a redundant description will be omitted.

Referring to FIG. 18, at least one second deposition stop layer 271 and at least one third deposition stop layer 272 may be disposed in the first transmissive area TA1 of the first optical area DA1.

An area of the second deposition stop layer 271 may be equal to an area of the third deposition stop layer 272.

Further, a shape of the second deposition stop layer 271 may be the same as a shape of the third deposition stop layer 272.

In this case, the second deposition stop layer 271 and the third deposition stop layer 272 may be formed using the same mask or may be formed using different masks.

As illustrated in FIG. 18, a transmittance of the first transmissive area TA1 included in the first optical area DA1 is adjusted and the UV reliability is ensured by adjusting an area and a shape of the second deposition stop layer 271 and an area and a shape of the third deposition stop layer 272.

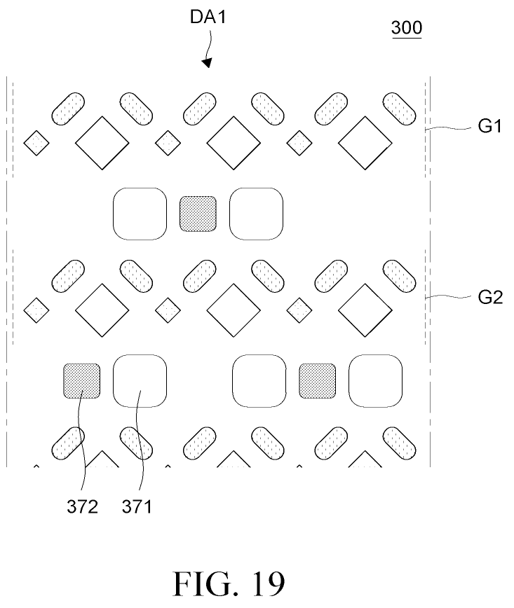

FIG. 19 is a plan view schematically illustrating a first optical area of a display device according to still another example embodiment of the present disclosure.

A display device 300 of FIG. 19 is substantially the same as the display device 100 of FIG. 9 except for a placement of an emission area EA of a green sub pixel Green SP, a placement of a plurality of second deposition stop layers 371 and a plurality of third deposition stop layers 372, so that a redundant description will be omitted.

Referring to FIG. 19, emission areas EA disposed in n-th rows, among the plurality of emission areas EA disposed in the first optical area DA1, may be emission areas EA of the plurality of green sub pixels Green SP. Here, n may be an odd integer of 1 or larger. In another equivalent example, n may be an even integer of 0 or larger (e.g., n may be 0, 2, 4, etc.)

Among the plurality of emission areas EA disposed in the first optical area DA1, emission areas EA disposed in n+1-th rows may be emission areas EA of a plurality of blue sub pixels Blue SP and emission areas EA of a plurality of red sub pixels Red SP. The emission area EA of a blue sub pixel Blue SP and the emission area EA of a red sub pixel Red SP disposed in each n+1-th row may be alternately disposed.

The plurality of emission areas EA disposed in the first optical area DA1 may have a structure in which the placement of the n-th row and the placement of the n+1-th row are repeated.

For example, when it is assumed that a placement of a first row of the n-th rows and a first row of the n+1-th rows is a first group G1 and a placement of a second row of the n-th rows and a second row of the n+1-th rows is a second group G2, the first group G1 and the second group G2 may be alternately disposed with respect to the row direction.

Further, at least one second deposition stop layer 371 and at least one third deposition stop layer 372 may be disposed in an area between the first group G1 and the second group G2. Simply for convenience, an area between the first group G1 and the second group G2 is not considered to constitute one of the n-th rows or n+1-th rows.

The second deposition stop layer 371 and the third deposition stop layer 372 disposed between the first group G1 and the second group G2 may be disposed in the same row. At this time, the second deposition stop layer 371 and the third deposition stop layer 372 may be alternately disposed, but are not limited thereto.

Further, the second deposition stop layer 371 may be disposed in the same column as the emission area EA of the green sub pixels Green SP disposed in the first group G1 and the second group G2.

The third deposition stop layer 372 may be disposed in the same column as the emission area EA of another green sub pixels Green SP disposed in the first group G1 and the second group G2.

The second deposition stop layer 371 and the third deposition stop layer 372 disposed in the same row may be disposed to be spaced apart from each other.

The second deposition stop layer 371 and the third deposition stop layer 372 have different areas, but are not limited thereto.

Further, the second deposition stop layer 371 and the third deposition stop layer 372 may have a quadrangular shape on the planar surface, but are not limited thereto.

As described above, the process for forming the second deposition stop layer 371 and the third deposition stop layer 372 disposed in the first optical area DA1 may be easily performed by changing a position of the plurality of emission areas EA disposed in the first optical area DA1.

Specifically, at least one second deposition stop layer 371 and at least one third deposition stop layer 372 are disposed in an area between the first group G1 and the second group G2 in the first optical area DA1. Therefore, the mask used for the process for forming the second deposition stop layer 371 and the third deposition stop layer 372 may ensure a margin area.

Therefore, the reliability of the process for forming the second deposition stop layer 371 and the third deposition stop layer 372 in the first optical area DA1 may be improved.

Further, at least one second deposition stop layer 371 and at least one third deposition stop layer 372 are disposed in a part of the first transmissive area TA1 included in the first optical area DA1. Therefore, the second electrode 123 of the light emitting diode 120 may not be disposed in an area in which the second deposition stop layer 371 and the third deposition stop layer 372 are disposed. By doing this, the transmittance of the first transmissive area TA1 may be improved.

Further, in the remaining part of the first transmissive area TA1 of the first optical area DA1, the first sub electrode 123a, the second sub electrode 123b, and the third sub electrode 123c of the second electrode 123 of the light emitting diode 120 are sequentially laminated to improve the UV reliability of the first transmissive area TA1.

Further, the second electrode 123 of the light emitting diode 120 disposed in the low transmissive area LTA of the first optical area DA1 includes the third sub electrode 123c so that the luminous efficiency of the light emitting diode 120 may be improved by the micro cavity effect of the light emitting diode 120.

The terms, such as a 1-1-th element, a 2-1-th element, a 1-2-th element, a 2-2-th element and the like, may respectively be referred to as a first-first element, a second-first element, a first-second element, a second-second element and the like. These terms are intended to identify the corresponding element(s) from the other element(s), and these are not used to define the essence, basis, order, or number of the elements. In an example, an element may be an electrode, a sub electrode, or another item.

Unless the context clearly indicates otherwise, an element may include multiple elements. Unless the context clearly indicates otherwise, a line may include multiple lines; a first horizontal line HL1 may include multiple first horizontal lines HL1; a second horizontal line HL2 may include multiple second horizontal lines HL2; a first vertical line VL1 may include multiple first vertical lines VL1; a second vertical line VL2 may include multiple second vertical lines VL2; and a normal vertical line VLn may include multiple normal vertical lines VLn.

Unless the context clearly indicates otherwise, an area may include multiple areas; an emission area EA may include multiple emission areas EA.

Various examples and aspects of the present disclosure are described below. These are provided as examples, and do not limit the scope of the present disclosure.

According to one or more example embodiments of the present disclosure, there is provided a display device. The display device includes a substrate, an optical area which includes a first emission area and a transmissive area, and a normal area which includes a second emission area and encloses the optical area. The display device further includes a planarization layer which is disposed on the substrate and is disposed in the optical area and the normal area. The display device further includes a first light emitting diode which is disposed on the planarization layer in the second emission area and includes a first-first electrode, a first organic layer disposed on the first-first electrode, and a second-first electrode disposed on the first organic layer. The display device further includes a first deposition stop layer disposed on the second-first electrode in the second emission area and at least one second deposition stop layer disposed on the planarization layer in a part of the transmissive area.

The second-first electrode disposed in the second emission area may include a first-first sub electrode disposed on the first organic layer and a second-first sub electrode disposed on the first-first sub electrode.

The first deposition stop layer may be disposed on the second-first sub electrode.

The display device may further include a second light emitting diode which is disposed on the planarization layer in the first emission area and includes a first-second electrode, a second organic layer disposed on the first-second electrode, and a second-second electrode disposed on the second organic layer. The second organic layer disposed in the first emission area may extend to a partial area of the transmissive area.

The second organic layer disposed in the first emission area may include a hole injection layer, a hole transport layer disposed on the hole injection layer, an emission layer disposed on the hole transport layer, an electron transport layer disposed on the emission layer, and an electron injection layer disposed on the electron transport layer and at least one of the hole injection layer, the hole transport layer, the electron transport layer, and the electron injection layer may be disposed in the transmissive area.

The second-second electrode disposed in the first emission area may include a first-second sub electrode disposed on the second organic layer, a second-second sub electrode disposed on the first-second sub electrode, and a third sub electrode disposed on the second-second sub electrode.

A thickness of the second-second electrode disposed in the first emission area may be larger than a thickness of the second-first electrode disposed in the second emission area.

The display device may further include at least one third deposition stop layer which is disposed on the planarization layer in another part of the transmissive area and is spaced apart from the second deposition stop layer.

The second-second electrode disposed in the first emission area may include a first-second sub electrode disposed on the second organic layer, a second-second sub electrode disposed on the first-second sub electrode, and a third sub electrode disposed on the second-second sub electrode and the first-second sub electrode, the second-second sub electrode, and the third sub electrode may be sequentially laminated in the remaining area excluding an area of the transmissive area in which the second deposition stop layer and the third deposition stop layer are disposed.

A height of the second deposition stop layer may be equal to a height of the third deposition stop layer.

A height of the first deposition stop layer may be lower than a height of the second deposition stop layer and a height of the third deposition stop layer.

The first deposition stop layer may be disposed on a different layer from the second deposition stop layer and the third deposition stop layer and the second deposition stop layer may be disposed on the same layer as the third deposition stop layer.

A plurality of first emission areas may include a plurality of first color emission areas, a plurality of second color emission areas, and a plurality of third color emission areas, and in the optical area, the plurality of first color emission areas may be disposed in n-th rows (where n is an odd integer of 1 or larger) and may be spaced apart from each other, and the plurality of second color emission areas and the plurality of third color emission areas may be disposed in 4k-th rows (where k is an integer of 1 or larger). A second color emission area and a third color emission area may be alternately arranged in each of the 4k-th rows.

In an example, in the optical area, the plurality of first color emission areas may be disposed in odd-numbered rows and may be spaced apart from each other. In the optical area, the plurality of second color emission areas and the plurality of third color emission areas may be disposed in some rows, and a second color emission area and a third color emission area may be alternately arranged in each of the some rows. The some rows may exclude rows occupied by the plurality of first color emission areas.

The second deposition stop layer may be disposed between respective first color emission areas disposed in a respective odd-numbered row. The third deposition stop layer may be disposed between respective first color emission areas disposed in a respective odd-numbered row.

The second deposition stop layer may be disposed between two respective first color emission areas in a row direction and between two respective first color emission areas in a column direction. The third deposition stop layer may be disposed between two respective first color emission areas in the row direction and between two respective first color emission areas in the column direction.

A first group may include: first color emission areas disposed in a first row; and second color emission areas and third color emission areas disposed in a second row. A second group may include first color emission areas disposed in a third row; and second color emission areas and third color emission areas disposed in a fourth row. The second deposition stop layer and the third deposition stop layer may be disposed in an area between the first group and the second group. The plurality of first color emission areas may include the first color emission areas included in the first group and the first color emission areas included in the second group. The plurality of second color emission areas may include the second color emission areas included in the first group and the second color emission areas included in the second group. The plurality of third color emission areas may include the third color emission areas included in the first group and the third color emission areas included in the second group.

The second deposition stop layer may be disposed between two respective first color emission areas in a column direction. The third deposition stop layer may be disposed between two respective first color emission areas in the column direction.

The normal area may include a non-emission area which encloses the second emission area, and the first deposition stop layer may be disposed in the non-emission area.

According to one or more example embodiments of the present disclosure, there is provided a display device. The display device includes a substrate, an optical area which includes a first emission area and a transmissive area, and a normal area which includes a second emission area. The display device further includes: a first light emitting diode which is disposed in the second emission area and includes a first-first electrode, a first organic layer disposed on the first-first electrode, and a second-first electrode disposed on the first organic layer; and a second light emitting diode which is disposed in the first emission area and includes a first-second electrode, a second organic layer disposed on the first-second electrode, and a second-second electrode disposed on the second organic layer. A thickness of the second-second electrode of the second light emitting diode may be greater than a thickness of the second-first electrode of the first light emitting diode.

The display device may further include: a bank; a first deposition stop layer disposed on the second-first electrode in the second emission area; and at least one second deposition stop layer disposed in a part of the transmissive area. The bank may have a first opening for the first light emitting diode and a second opening for the second light emitting diode. The second-second electrode may be disposed in a second part of the transmissive area and is not disposed in the part of the transmissive area.

The first deposition stop layer may be disposed in the entire normal area.

In one or more examples, the first deposition stop layer is not disposed in the optical area.

The first deposition stop layer may be disposed on the second-first electrode of the first light emitting diode.

In one or more examples, the first deposition stop layer is not disposed on the second-second electrode of the second light emitting diode.

In one or more examples, at least a top layer of the second-second electrode is not disposed on the first deposition stop layer.

The description herein has been presented to enable any person skilled in the art to make, use and practice the technical features of the present disclosure, and has been provided in the context of one or more particular example applications and their example requirements. Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
an optical area which includes a first emission area and a transmissive area;
a normal area which includes a second emission area and encloses the optical area;
a planarization layer which is disposed on the substrate and is disposed in the optical area and the normal area;
a first light emitting diode which is disposed on the planarization layer in the second emission area and includes a first-first electrode, a first organic layer disposed on the first-first electrode, and a second-first electrode disposed on the first organic layer;
a first deposition stop layer disposed on the second-first electrode in the second emission area; and
at least one second deposition stop layer disposed on the planarization layer in a part of the transmissive area.

2. The display device according to claim 1, wherein the second-first electrode disposed in the second emission area includes a first-first sub electrode disposed on the first organic layer and a second-first sub electrode disposed on the first-first sub electrode.

3. The display device according to claim 2, wherein the first deposition stop layer is disposed on the second-first sub electrode.

4. The display device according to claim 1, further comprising:
a second light emitting diode which is disposed on the planarization layer in the first emission area and includes a first-second electrode, a second organic layer disposed on the first-second electrode, and a second-second electrode disposed on the second organic layer,
wherein the second organic layer disposed in the first emission area extends to a partial area of the transmissive area.

5. The display device according to claim 4, wherein the second organic layer disposed in the first emission area includes a hole injection layer, a hole transport layer disposed on the hole injection layer, an emission layer disposed on the hole transport layer, an electron transport layer disposed on the emission layer, and an electron injection layer disposed on the electron transport layer, and
wherein at least one of the hole injection layer, the hole transport layer, the electron transport layer, and the electron injection layer is disposed in the transmissive area.

6. The display device according to claim 4, wherein the second-second electrode disposed in the first emission area includes a first-second sub electrode disposed on the second organic layer, a second-second sub electrode disposed on the first-second sub electrode, and a third sub electrode disposed on the second-second sub electrode.

7. The display device according to claim 4, wherein a thickness of the second-second electrode disposed in the first emission area is greater than a thickness of the second-first electrode disposed in the second emission area.

8. The display device according to claim 4, further comprising:
at least one third deposition stop layer which is disposed on the planarization layer in another part of the transmissive area and is spaced apart from the at least one second deposition stop layer.

9. The display device according to claim 8, wherein the second-second electrode disposed in the first emission area includes a first-second sub electrode disposed on the second organic layer, a second-second sub electrode disposed on the first-second sub electrode, and a third sub electrode disposed on the second-second sub electrode,
wherein the first-second sub electrode, the second-second sub electrode, and the third sub electrode are sequentially laminated in a remaining area of the transmissive area, and
wherein the remaining area of the transmissive area excludes an area of the transmissive area in which the at least one second deposition stop layer is disposed and excludes an area of the transmissive area in which the at least one third deposition stop layer is disposed.

10. The display device according to claim 8, wherein a height of the at least one second deposition stop layer is equal to a height of the at least one third deposition stop layer.

11. The display device according to claim 8, wherein a height of the first deposition stop layer is less than a height of the at least one second deposition stop layer and is less than a height of the at least one third deposition stop layer.

12. The display device according to claim 8, wherein the first deposition stop layer is disposed on a different layer than a layer on which the at least one second deposition stop layer and the at least one third deposition stop layer are disposed, and
wherein the at least one second deposition stop layer is disposed on a same layer as the at least one third deposition stop layer.

13. The display device according to claim 8, wherein a plurality of first emission areas includes a plurality of first color emission areas, a plurality of second color emission areas, and a plurality of third color emission areas,
wherein in the optical area, the plurality of first color emission areas is disposed in odd-numbered rows and is spaced apart from each other, and
wherein in the optical area, the plurality of second color emission areas and the plurality of third color emission areas are disposed in some rows, and a second color emission area and a third color emission area are alternately arranged in each of the some rows, and
wherein the some rows exclude rows occupied by the plurality of first color emission areas.

14. The display device according to claim 13, wherein the at least one second deposition stop layer is disposed between respective first color emission areas disposed in a respective odd-numbered row, and
wherein the at least one third deposition stop layer is disposed between respective first color emission areas disposed in a respective odd-numbered row.

15. The display device according to claim 14, wherein the at least one second deposition stop layer is disposed between two corresponding first color emission areas in a row direction and between two corresponding first color emission areas in a column direction, and
wherein the at least one third deposition stop layer is disposed between two respective first color emission areas in the row direction and between two respective first color emission areas in the column direction.

16. The display device according to claim 13, wherein a first group includes: first color emission areas disposed in a first row; and second color emission areas and third color emission areas disposed in a second row,
wherein a second group includes: first color emission areas disposed in a third row; and second color emission areas and third color emission areas disposed in a fourth row,
wherein the at least one second deposition stop layer and the at least one third deposition stop layer are disposed in an area between the first group and the second group,
wherein the plurality of first color emission areas include the first color emission areas included in the first group and the first color emission areas included in the second group,
wherein the plurality of second color emission areas include the second color emission areas included in the first group and the second color emission areas included in the second group, and
wherein the plurality of third color emission areas include the third color emission areas included in the first group and the third color emission areas included in the second group.

17. The display device according to claim 16, wherein the at least one second deposition stop layer is disposed between two respective first color emission areas in a column direction, and
wherein the at least one third deposition stop layer is disposed between two respective first color emission areas in the column direction.

18. The display device according to claim 1, wherein the normal area includes a non-emission area which encloses the second emission area, and
wherein the first deposition stop layer is disposed in the non-emission area.

19. A display device, comprising:
a substrate;
an optical area which includes a first emission area and a transmissive area;
a normal area which includes a second emission area;
a first light emitting diode which is disposed in the second emission area and includes a first-first electrode, a first organic layer disposed on the first-first electrode, and a second-first electrode disposed on the first organic layer; and
a second light emitting diode which is disposed in the first emission area and includes a first-second electrode, a second organic layer disposed on the first-second electrode, and a second-second electrode disposed on the second organic layer,
wherein a thickness of the second-second electrode of the second light emitting diode is greater than a thickness of the second-first electrode of the first light emitting diode.

20. The display device according to claim 19, further comprising:
a bank;
a first deposition stop layer disposed on the second-first electrode in the second emission area; and
at least one second deposition stop layer disposed in a part of the transmissive area,
wherein the bank has a first opening for the first light emitting diode and a second opening for the second light emitting diode, and
wherein the second-second electrode is disposed in a second part of the transmissive area and is not disposed in the part of the transmissive area.
